(19) United States
(12) Patent Application Publication
(10) Pub. No.: US 2025/0038816 A1
(43) Pub. Date: Jan. 30, 2025

(54) PRE-PROCESSING FOR CSI COMPRESSION IN WIRELESS SYSTEMS

(71) Applicants: InterDigital Patent Holdings, Inc., Wilmington, DE (US); IDAC HOLDINGS, INC., Wilmington (DE)

(72) Inventors: Mihaela Beluri, Jericho, NY (US); J. Patrick Tooher, Montreal (CA); Arnab Roy, Phoenixville, PA (US); Tejaswinee Lutchoomun, Montreal (CA); Mohamed Salah Ibrahim, Chesterbrook, PA (US); Satyanarayana Katla, London (GB); Ibrahim Hemadeh, Hemel Hempstead (GB); Yugeswar Deenoo Narayanan Thangaraj, Chalfont, PA (US); Moon-il Lee, Melville, NY (US); Ghyslain Pelletier, Montreal (CA)

(73) Assignee: InterDigital Patent Holdings, Inc., Wilmington, DE (US)

(21) Appl. No.: 18/713,957

(22) PCT Filed: Nov. 30, 2022
(86) PCT No.: PCT/US2022/051400

§ 371 Date: May 28, 2024

Related U.S. Application Data
(60) Provisional application No. 63/284,404, filed on Nov. 30, 2021.
(60) Provisional application No. 63/308,234, filed on Feb. 9, 2022.

(51) Int. Cl. H04B 7/06

(52) U.S. Cl. CPC H04B 7/0658; H04B 7/0626

(57) ABSTRACT

Systems, methods, and instrumentalities are disclosed herein for pre-processing for channel state information (CSI) compression in wireless system. A WTRU may receive configuration information that indicates a reference signal and a data processing model for channel state information (CSI) compression. The WTRU may determine CSI associated with a channel using the reference signal. The WTRU may determine a channel condition associated with pre-processing. The WTRU may select a pre-processing type from a plurality of pre-processing types based on the data processing model and the determined channel condition associated with pre-processing. The WTRU may pre-process the CSI associated with the channel based on the selected pre-processing type. The WTRU may generate compressed CSI by compressing the pre-processed CSI using the data processing model for CSI compression. The WTRU may send the compressed CSI to a network.

### CROSS-REFERENCE TO RELATED APPLICATIONS

This application claims the benefit of U.S. Provisional Application No. 63/284,404, filed Nov. 30, 2021 and U.S. Provisional Application No. 63/308,234, filed Feb. 9, 2022, the contents of which are incorporated by reference herein.

### BACKGROUND

Mobile communications using wireless communication continue to evolve. A fifth generation of mobile communication radio access technology (RAT) may be referred to as 5G new radio (NR). A previous (legacy) generation of mobile communication RAT may be, for example, fourth generation (4G) long term evolution (LTE). Wireless communication devices may establish communications with other devices and data networks, e.g., via an access network, such as a radio access network (RAN).

### SUMMARY

Systems, methods, and instrumentalities are described herein related to pre-processing for channel state information (CSI) compression in wireless systems.

A wireless transmit/receive unit (WTRU) may include a processor configured to perform one or more actions. The WTRU may receive configuration information that indicates a reference signal and a data processing model (e.g., AI NN encoder model) for channel state information (CSI) compression. The WTRU may determine CSI associated with a channel using the reference signal. The WTRU may determine a channel condition associated with pre-processing. The WTRU may select a pre-processing type from a plurality of pre-processing types based on the data processing model and the determined channel condition associated with pre-processing. The WTRU may pre-process the CSI associated with the channel based on the selected pre-processing type. The WTRU may generate compressed CSI by compressing the pre-processed CSI using the data processing model for CSI compression. The WTRU may send the compressed CSI to a network.

The WTRU may send an indication of the selected pre-processing type to the network. The WTRU may determine the channel condition associated with pre-processing based on a value of a channel measurement parameter. The channel measurement parameter may include a coherence bandwidth. The channel condition may be whether a coherence bandwidth is above or below a threshold.

The selection of the pre-processing type based on the data processing model may be based on a determination that the data processing model supports the pre-processing type. The pre-processing type may include at least one of: spatial domain pre-processing, frequency domain pre-processing, angle-delay domain pre-processing, time domain pre-processing, or linear transformation pre-processing.

### BRIEF DESCRIPTION OF THE DRAWINGS

FIG. 1A is a system diagram illustrating an example communications system in which one or more disclosed embodiments may be implemented.

FIG. 1B is a system diagram illustrating an example wireless transmit/receive unit (WTRU) that may be used within the communications system illustrated in FIG. 1A according to an embodiment.

FIG. 1C is a system diagram illustrating an example radio access network (RAN) and an example core network (CN) that may be used within the communications system illustrated in FIG. 1A according to an embodiment.

FIG. 1D is a system diagram illustrating a further example RAN and a further example CN that may be used within the communications system illustrated in FIG. 1A according to an embodiment.

FIG. 2 shows an example of a channel state information (CSI) measurement setting.

FIG. 3 shows an example of codebook-based precoding with feedback information.

FIG. 4 shows an example of autoencoders (AEs) for CSI compression.

FIG. 5 shows an example of a block diagram of an AE.

FIG. 6 shows an example of AEs for CSI compression with pre-processing at the AI NN encoder input.

FIG. 7 shows an example of a block diagram of DNN.

FIG. 8 shows an example of a block diagram of CNN.

FIG. 9 shows an example of averaging in spatial-domain for pre-processing of an 8-by-8 matrix.

FIG. 10 shows an example of spatial-domain pre-processing.

FIG. 11 shows an example of a CSI block over space, time, and frequency.

FIG. 12 shows an example of a reduced-size CSI block over space, time, and frequency.

FIG. 13 shows an example of spatial-domain pre-processing.

FIG. 14 shows an example of a channel vector at the (nᵣ, nₜ)-th element at the t-th time slot and the reduced size vector.

FIG. 15 shows an example of frequency-domain pre-processing.

FIG. 16 shows an example of time-domain channel vector at the (nᵣ, nₜ)-th element at the no-th sub-carrier and the reduced size vector.

FIG. 17 shows an example of time-domain pre-processing.

FIG. 18 shows an example of inputs and outputs into and from each pre-processing technique.

FIG. 19 shows an example of multi-input-multi-output AE.

FIG. 20 shows an example of WTRU autonomous selection of pre-processing type.

### DETAILED DESCRIPTION

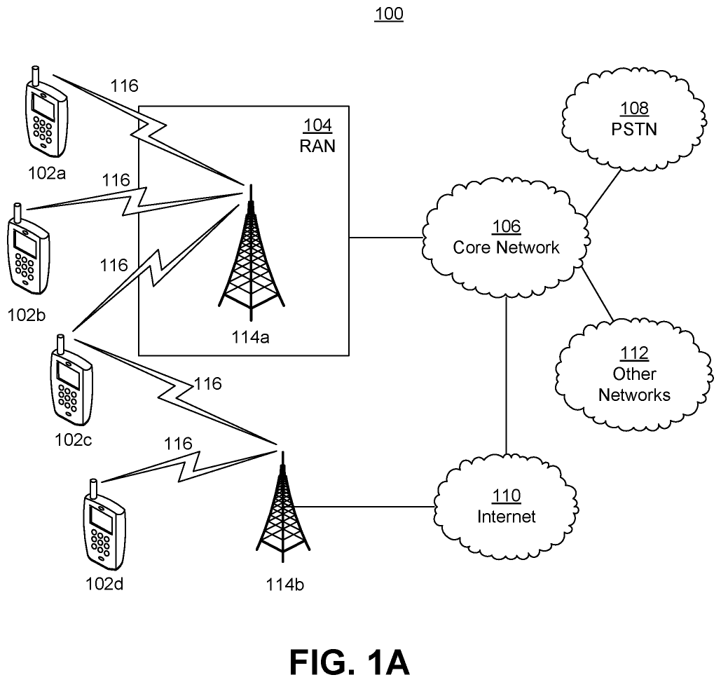

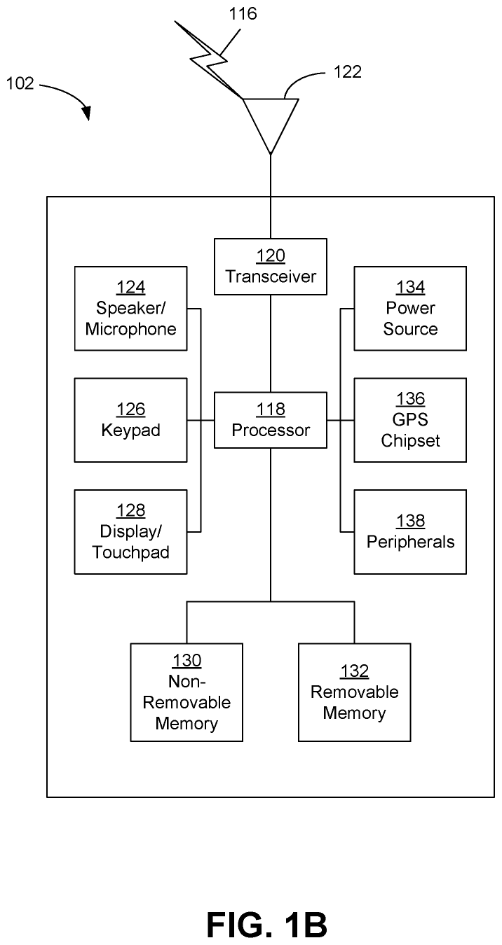

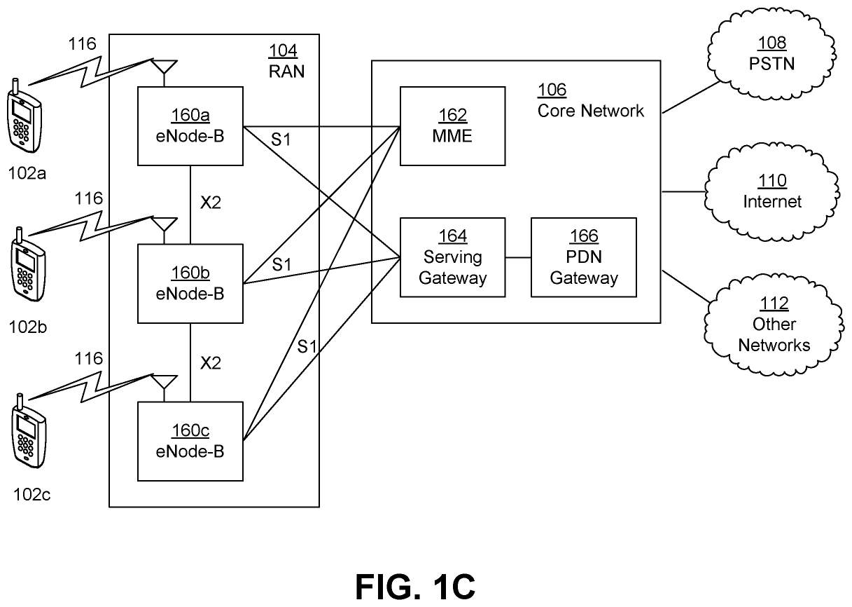

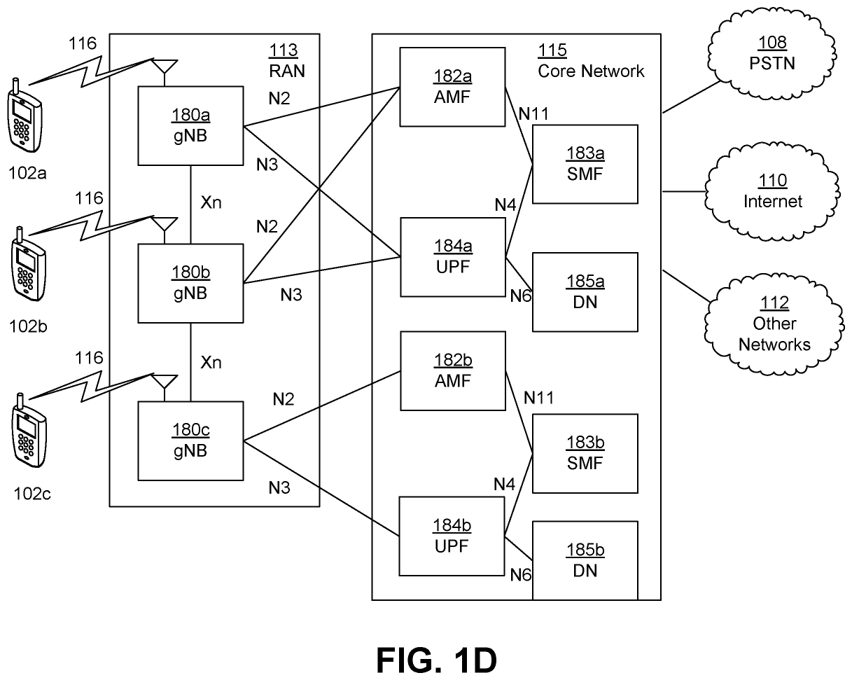

FIG. 1A is a diagram illustrating an example communications system 100 in which one or more disclosed embodiments may be implemented. The communications system 100 may be a multiple access system that provides content, such as voice, data, video, messaging, broadcast, etc., to multiple wireless users. The communications system 100 may enable multiple wireless users to access such content through the sharing of system resources, including wireless bandwidth. For example, the communications systems 100 may employ one or more channel access methods, such as code division multiple access (CDMA), time division multiple access (TDMA), frequency division multiple access (FDMA), orthogonal FDMA (OFDMA), single-carrier FDMA (SC-FDMA), zero-tail unique-word DFT-Spread OFDM (ZT UW DTS-s OFDM), unique word OFDM (UW-OFDM), resource block-filtered OFDM, filter bank multicarrier (FBMC), and the like.

As shown in FIG. 1A, the communications system 100 may include wireless transmit/receive units (WTRUs) 102a, 102b, 102c, 102d, a RAN 104/113, a CN 106/115, a public switched telephone network (PSTN) 108, the Internet 110, and other networks 112, though it will be appreciated that the disclosed embodiments contemplate any number of WTRUs, base stations, networks, and/or network elements. Each of the WTRUs 102a, 102b, 102c, 102d may be any type of device configured to operate and/or communicate in a wireless environment. By way of example, the WTRUs 102a, 102b, 102c, 102d, any of which may be referred to as a “station” and/or a “STA”, may be configured to transmit and/or receive wireless signals and may include a user equipment (UE), a mobile station, a fixed or mobile subscriber unit, a subscription-based unit, a pager, a cellular telephone, a personal digital assistant (PDA), a smartphone, a laptop, a netbook, a personal computer, a wireless sensor, a hotspot or Mi-Fi device, an Internet of Things (IoT) device, a watch or other wearable, a head-mounted display (HMD), a vehicle, a drone, a medical device and applications (e.g., remote surgery), an industrial device and applications (e.g., a robot and/or other wireless devices operating in an industrial and/or an automated processing chain contexts), a consumer electronics device, a device operating on commercial and/or industrial wireless networks, and the like. Any of the WTRUs 102a, 102b, 102c and 102d may be interchangeably referred to as a UE.

The communications systems 100 may also include a base station 114a and/or a base station 114b. Each of the base stations 114a, 114b may be any type of device configured to wirelessly interface with at least one of the WTRUs 102a, 102b, 102c, 102d to facilitate access to one or more communication networks, such as the CN 106/115, the Internet 110, and/or the other networks 112. By way of example, the base stations 114a, 114b may be a base transceiver station (BTS), a Node-B, an encode B, a Home Node B, a Home eNode B, a gNB, a NR NodeB, a site controller, an access point (AP), a wireless router, and the like. While the base stations 114a, 114b are each depicted as a single element, it will be appreciated that the base stations 114a, 114b may include any number of interconnected base stations and/or network elements.

The base station 114a may be part of the RAN 104/113, which may also include other base stations and/or network elements (not shown), such as a base station controller (BSC), a radio network controller (RNC), relay nodes, etc. The base station 114a and/or the base station 114b may be configured to transmit and/or receive wireless signals on one or more carrier frequencies, which may be referred to as a cell (not shown). These frequencies may be in licensed spectrum, unlicensed spectrum, or a combination of licensed and unlicensed spectrum. A cell may provide coverage for a wireless service to a specific geographical area that may be relatively fixed or that may change over time. The cell may further be divided into cell sectors. For example, the cell associated with the base station 114a may be divided into three sectors. Thus, in one embodiment, the base station 114a may include three transceivers, i.e., one for each sector of the cell. In an embodiment, the base station 114a may employ multiple-input multiple output (MIMO) technology and may utilize multiple transceivers for each sector of the cell. For example, beamforming may be used to transmit and/or receive signals in desired spatial directions.

The base stations 114a, 114b may communicate with one or more of the WTRUs 102a, 102b, 102c, 102d over an air interface 116, which may be any suitable wireless communication link (e.g., radio frequency (RF), microwave, centimeter wave, micrometer wave, infrared (IR), ultraviolet (UV), visible light, etc.). The air interface 116 may be established using any suitable radio access technology (RAT).

More specifically, as noted above, the communications system 100 may be a multiple access system and may employ one or more channel access schemes, such as CDMA, TDMA, FDMA, OFDMA, SC-FDMA, and the like. For example, the base station 114a in the RAN 104/113 and the WTRUs 102a, 102b, 102c may implement a radio technology such as Universal Mobile Telecommunications System (UMTS) Terrestrial Radio Access (UTRA), which may establish the air interface 115/116/117 using wideband CDMA (WCDMA). WCDMA may include communication protocols such as High-Speed Packet Access (HSPA) and/or Evolved HSPA (HSPA+). HSPA may include High-Speed Downlink (DL) Packet Access (HSDPA) and/or High-Speed UL Packet Access (HSUPA).

In an embodiment, the base station 114a and the WTRUs 102a, 102b, 102c may implement a radio technology such as Evolved UMTS Terrestrial Radio Access (E-UTRA), which may establish the air interface 116 using Long Term Evolution (LTE) and/or LTE-Advanced (LTE-A) and/or LTE-Advanced Pro (LTE-A Pro).

In an embodiment, the base station 114a and the WTRUs 102a, 102b, 102c may implement a radio technology such as NR Radio Access, which may establish the air interface 116 using New Radio (NR).

In an embodiment, the base station 114a and the WTRUs 102a, 102b, 102c may implement multiple radio access technologies. For example, the base station 114a and the WTRUs 102a, 102b, 102c may implement LTE radio access and NR radio access together, for instance using dual connectivity (DC) principles. Thus, the air interface utilized by WTRUs 102a, 102b, 102c may be characterized by multiple types of radio access technologies and/or transmissions sent to/from multiple types of base stations (e.g., an eNB and a gNB).

In other embodiments, the base station 114a and the WTRUs 102a, 102b, 102c may implement radio technologies such as IEEE 802.11 (i.e., Wireless Fidelity (WiFi), IEEE 802.16 (i.e., Worldwide Interoperability for Microwave Access (WiMAX)), CDMA2000, CDMA2000 1×, CDMA2000 EV-DO, Interim Standard 2000 (IS-2000), Interim Standard 95 (IS-95), Interim Standard 856 (IS-856), Global System for Mobile communications (GSM), Enhanced Data rates for GSM Evolution (EDGE), GSM EDGE (GERAN), and the like.

The base station 114b in FIG. 1A may be a wireless router, Home Node B, Home eNode B, or access point, for example, and may utilize any suitable RAT for facilitating wireless connectivity in a localized area, such as a place of business, a home, a vehicle, a campus, an industrial facility, an air corridor (e.g., for use by drones), a roadway, and the like. In one embodiment, the base station 114b and the WTRUs 102c, 102d may implement a radio technology such as IEEE 802.11 to establish a wireless local area network (WLAN). In an embodiment, the base station 114b and the WTRUs 102c, 102d may implement a radio technology such as IEEE 802.15 to establish a wireless personal area network (WPAN). In yet another embodiment, the base station 114b and the WTRUs 102c, 102d may utilize a cellular-based RAT (e.g., WCDMA, CDMA2000, GSM, LTE, LTE-A, LTE-A Pro, NR, etc.) to establish a picocell or femtocell. As shown in FIG. 1A, the base station 114b may have a direct connection to the Internet 110. Thus, the base station 114b may not be required to access the Internet 110 via the CN 106/115.

The RAN 104/113 may be in communication with the CN 106/115, which may be any type of network configured to provide voice, data, applications, and/or voice over internet protocol (VoIP) services to one or more of the WTRUs 102a, 102b, 102c, 102d. The data may have varying quality of service (QOS) requirements, such as differing throughput requirements, latency requirements, error tolerance requirements, reliability requirements, data throughput requirements, mobility requirements, and the like. The CN 106/115 may provide call control, billing services, mobile location-based services, pre-paid calling, Internet connectivity, video distribution, etc., and/or perform high-level security functions, such as user authentication. Although not shown in FIG. 1A, it will be appreciated that the RAN 104/113 and/or the CN 106/115 may be in direct or indirect communication with other RANs that employ the same RAT as the RAN 104/113 or a different RAT. For example, in addition to being connected to the RAN 104/113, which may be utilizing a NR radio technology, the CN 106/115 may also be in communication with another RAN (not shown) employing a GSM, UMTS, CDMA 2000, WiMAX, E-UTRA, or WiFi radio technology.

The CN 106/115 may also serve as a gateway for the WTRUs 102a, 102b, 102c, 102d to access the PSTN 108, the Internet 110, and/or the other networks 112. The PSTN 108 may include circuit-switched telephone networks that provide plain old telephone service (POTS). The Internet 110 may include a global system of interconnected computer networks and devices that use common communication protocols, such as the transmission control protocol (TCP), user datagram protocol (UDP) and/or the internet protocol (IP) in the TCP/IP internet protocol suite. The networks 112 may include wired and/or wireless communications networks owned and/or operated by other service providers. For example, the networks 112 may include another CN connected to one or more RANs, which may employ the same RAT as the RAN 104/113 or a different RAT.

Some or all of the WTRUs 102a, 102b, 102c, 102d in the communications system 100 may include multi-mode capabilities (e.g., the WTRUs 102a, 102b, 102c, 102d may include multiple transceivers for communicating with different wireless networks over different wireless links). For example, the WTRU 102c shown in FIG. 1A may be configured to communicate with the base station 114a, which may employ a cellular-based radio technology, and with the base station 114b, which may employ an IEEE 802 radio technology.

FIG. 1B is a system diagram illustrating an example WTRU 102. As shown in FIG. 1B, the WTRU 102 may include a processor 118, a transceiver 120, a transmit/receive element 122, a speaker/microphone 124, a keypad 126, a display/touchpad 128, non-removable memory 130, removable memory 132, a power source 134, a global positioning system (GPS) chipset 136, and/or other peripherals 138, among others. It will be appreciated that the WTRU 102 may include any sub-combination of the foregoing elements while remaining consistent with an embodiment.

The processor 118 may be a general purpose processor, a special purpose processor, a conventional processor, a digital signal processor (DSP), a plurality of microprocessors, one or more microprocessors in association with a DSP core, a controller, a microcontroller, Application Specific Integrated Circuits (ASICs), Field Programmable Gate Arrays (FPGAs) circuits, any other type of integrated circuit (IC), a state machine, and the like. The processor 118 may perform signal coding, data processing, power control, input/output processing, and/or any other functionality that enables the WTRU 102 to operate in a wireless environment. The processor 118 may be coupled to the transceiver 120, which may be coupled to the transmit/receive element 122. While FIG. 1B depicts the processor 118 and the transceiver 120 as separate components, it will be appreciated that the processor 118 and the transceiver 120 may be integrated together in an electronic package or chip.

The transmit/receive element 122 may be configured to transmit signals to, or receive signals from, a base station (e.g., the base station 114a) over the air interface 116. For example, in one embodiment, the transmit/receive element 122 may be an antenna configured to transmit and/or receive RF signals. In an embodiment, the transmit/receive element 122 may be an emitter/detector configured to transmit and/or receive IR, UV, or visible light signals, for example. In yet another embodiment, the transmit/receive element 122 may be configured to transmit and/or receive both RF and light signals. It will be appreciated that the transmit/receive element 122 may be configured to transmit and/or receive any combination of wireless signals.

Although the transmit/receive element 122 is depicted in FIG. 1B as a single element, the WTRU 102 may include any number of transmit/receive elements 122. More specifically, the WTRU 102 may employ MIMO technology. Thus, in one embodiment, the WTRU 102 may include two or more transmit/receive elements 122 (e.g., multiple antennas) for transmitting and receiving wireless signals over the air interface 116.

The transceiver 120 may be configured to modulate the signals that are to be transmitted by the transmit/receive element 122 and to demodulate the signals that are received by the transmit/receive element 122. As noted above, the WTRU 102 may have multi-mode capabilities. Thus, the transceiver 120 may include multiple transceivers for enabling the WTRU 102 to communicate via multiple RATs, such as NR and IEEE 802.11, for example.

The processor 118 of the WTRU 102 may be coupled to, and may receive user input data from, the speaker/microphone 124, the keypad 126, and/or the display/touchpad 128 (e.g., a liquid crystal display (LCD) display unit or organic light-emitting diode (OLED) display unit). The processor 118 may also output user data to the speaker/microphone 124, the keypad 126, and/or the display/touchpad 128. In addition, the processor 118 may access information from, and store data in, any type of suitable memory, such as the non-removable memory 130 and/or the removable memory 132. The non-removable memory 130 may include random-access memory (RAM), read-only memory (ROM), a hard disk, or any other type of memory storage device. The removable memory 132 may include a subscriber identity module (SIM) card, a memory stick, a secure digital (SD) memory card, and the like. In other embodiments, the processor 118 may access information from, and store data in, memory that is not physically located on the WTRU 102, such as on a server or a home computer (not shown).

The processor 118 may receive power from the power source 134 and may be configured to distribute and/or control the power to the other components in the WTRU 102. The power source 134 may be any suitable device for powering the WTRU 102. For example, the power source 134 may include one or more dry cell batteries (e.g., nickel-cadmium (NiCd), nickel-zinc (NiZn), nickel metal hydride (NiMH), lithium-ion (Li-ion), etc.), solar cells, fuel cells, and the like.

The processor 118 may also be coupled to the GPS chipset 136, which may be configured to provide location information (e.g., longitude and latitude) regarding the current location of the WTRU 102. In addition to, or in lieu of, the information from the GPS chipset 136, the WTRU 102 may receive location information over the air interface 116 from a base station (e.g., base stations 114a, 114b) and/or determine its location based on the timing of the signals being received from two or more nearby base stations. It will be appreciated that the WTRU 102 may acquire location information by way of any suitable location-determination method while remaining consistent with an embodiment.

The processor 118 may further be coupled to other peripherals 138, which may include one or more software and/or hardware modules that provide additional features, functionality and/or wired or wireless connectivity. For example, the peripherals 138 may include an accelerometer, an e-compass, a satellite transceiver, a digital camera (for photographs and/or video), a universal serial bus (USB) port, a vibration device, a television transceiver, a hands free headset, a Bluetooth® module, a frequency modulated (FM) radio unit, a digital music player, a media player, a video game player module, an Internet browser, a Virtual Reality and/or Augmented Reality (VR/AR) device, an activity tracker, and the like. The peripherals 138 may include one or more sensors, the sensors may be one or more of a gyroscope, an accelerometer, a hall effect sensor, a magnetometer, an orientation sensor, a proximity sensor, a temperature sensor, a time sensor; a geolocation sensor; an altimeter, a light sensor, a touch sensor, a magnetometer, a barometer, a gesture sensor, a biometric sensor, and/or a humidity sensor.

The WTRU 102 may include a full duplex radio for which transmission and reception of some or all of the signals (e.g., associated with particular subframes for both the UL (e.g., for transmission) and downlink (e.g., for reception) may be concurrent and/or simultaneous. The full duplex radio may include an interference management unit to reduce and or substantially eliminate self-interference via either hardware (e.g., a choke) or signal processing via a processor (e.g., a separate processor (not shown) or via processor 118). In an embodiment, the WRTU 102 may include a half-duplex radio for which transmission and reception of some or all of the signals (e.g., associated with particular subframes for either the UL (e.g., for transmission) or the downlink (e.g., for reception)).

FIG. 1C is a system diagram illustrating the RAN 104 and the CN 106 according to an embodiment. As noted above, the RAN 104 may employ an E-UTRA radio technology to communicate with the WTRUs 102a, 102b, 102c over the air interface 116. The RAN 104 may also be in communication with the CN 106.

The RAN 104 may include eNode-Bs 160a, 160b, 160c, though it will be appreciated that the RAN 104 may include any number of eNode-Bs while remaining consistent with an embodiment. The eNode-Bs 160a, 160b, 160c may each include one or more transceivers for communicating with the WTRUs 102a, 102b, 102c over the air interface 116. In one embodiment, the eNode-Bs 160a, 160b, 160c may implement MIMO technology. Thus, the eNode-B 160a, for example, may use multiple antennas to transmit wireless signals to, and/or receive wireless signals from, the WTRU 102a.

Each of the eNode-Bs 160a, 160b, 160c may be associated with a particular cell (not shown) and may be configured to handle radio resource management decisions, handover decisions, scheduling of users in the UL and/or DL, and the like. As shown in FIG. 1C, the eNode-Bs 160a, 160b, 160c may communicate with one another over an X2 interface.

The CN 106 shown in FIG. 1C may include a mobility management entity (MME) 162, a serving gateway (SGW) 164, and a packet data network (PDN) gateway (or PGW) 166. While each of the foregoing elements is depicted as part of the CN 106, it will be appreciated that any of these elements may be owned and/or operated by an entity other than the CN operator.

The MME 162 may be connected to each of the eNode-Bs 162a, 162b, 162c in the RAN 104 via an S1 interface and may serve as a control node. For example, the MME 162 may be responsible for authenticating users of the WTRUs 102a, 102b, 102c, bearer activation/deactivation, selecting a particular serving gateway during an initial attach of the WTRUs 102a, 102b, 102c, and the like. The MME 162 may provide a control plane function for switching between the RAN 104 and other RANs (not shown) that employ other radio technologies, such as GSM and/or WCDMA.

The SGW 164 may be connected to each of the eNode Bs 160a, 160b, 160c in the RAN 104 via the S1 interface. The SGW 164 may generally route and forward user data packets to/from the WTRUs 102a, 102b, 102c. The SGW 164 may perform other functions, such as anchoring user planes during inter-eNode B handovers, triggering paging when DL data is available for the WTRUs 102a, 102b, 102c, managing and storing contexts of the WTRUs 102a, 102b, 102c, and the like.

The SGW 164 may be connected to the PGW 166, which may provide the WTRUs 102a, 102b, 102c with access to packet-switched networks, such as the Internet 110, to facilitate communications between the WTRUs 102a, 102b, 102c and IP-enabled devices.

The CN 106 may facilitate communications with other networks. For example, the CN 106 may provide the WTRUs 102a, 102b, 102c with access to circuit-switched networks, such as the PSTN 108, to facilitate communications between the WTRUs 102a, 102b, 102c and traditional land-line communications devices. For example, the CN 106 may include, or may communicate with, an IP gateway (e.g., an IP multimedia subsystem (IMS) server) that serves as an interface between the CN 106 and the PSTN 108. In addition, the CN 106 may provide the WTRUs 102a, 102b, 102c with access to the other networks 112, which may include other wired and/or wireless networks that are owned and/or operated by other service providers.

Although the WTRU is described in FIGS. 1A-1D as a wireless terminal, it is contemplated that in certain representative embodiments that such a terminal may use (e.g., temporarily or permanently) wired communication interfaces with the communication network.

In representative embodiments, the other network 112 may be a WLAN.

A WLAN in Infrastructure Basic Service Set (BSS) mode may have an Access Point (AP) for the BSS and one or more stations (STAs) associated with the AP. The AP may have an access or an interface to a Distribution System (DS) or another type of wired/wireless network that carries traffic in to and/or out of the BSS. Traffic to STAs that originates from outside the BSS may arrive through the AP and may be delivered to the STAs. Traffic originating from STAs to destinations outside the BSS may be sent to the AP to be delivered to respective destinations. Traffic between STAs within the BSS may be sent through the AP, for example, where the source STA may send traffic to the AP and the AP may deliver the traffic to the destination STA. The traffic between STAs within a BSS may be considered and/or referred to as peer-to-peer traffic. The peer-to-peer traffic may be sent between (e.g., directly between) the source and destination STAs with a direct link setup (DLS). In certain representative embodiments, the DLS may use an 802.11e DLS or an 802.11z tunneled DLS (TDLS). A WLAN using an Independent BSS (IBSS) mode may not have an AP, and the STAs (e.g., all of the STAs) within or using the IBSS may communicate directly with each other. The IBSS mode of communication may sometimes be referred to herein as an “ad-hoc” mode of communication.

When using the 802.11ac infrastructure mode of operation or a similar mode of operations, the AP may transmit a beacon on a fixed channel, such as a primary channel. The primary channel may be a fixed width (e.g., 20 MHz wide bandwidth) or a dynamically set width via signaling. The primary channel may be the operating channel of the BSS and may be used by the STAs to establish a connection with the AP. In certain representative embodiments, Carrier Sense Multiple Access with Collision Avoidance (CSMA/CA) may be implemented, for example in in 802.11 systems. For CSMA/CA, the STAs (e.g., every STA), including the AP, may sense the primary channel. If the primary channel is sensed/detected and/or determined to be busy by a particular STA, the particular STA may back off. One STA (e.g., only one station) may transmit at any given time in a given BSS.

High Throughput (HT) STAs may use a 40 MHz wide channel for communication, for example, via a combination of the primary 20 MHz channel with an adjacent or nonadjacent 20 MHz channel to form a 40 MHz wide channel.

Very High Throughput (VHT) STAs may support 20 MHz, 40 MHZ, 80 MHZ, and/or 160 MHz wide channels. The 40 MHz, and/or 80 MHz, channels may be formed by combining contiguous 20 MHz channels. A 160 MHz channel may be formed by combining 8 contiguous 20 MHz channels, or by combining two non-contiguous 80 MHz channels, which may be referred to as an 80+80 configuration. For the 80+80 configuration, the data, after channel encoding, may be passed through a segment parser that may divide the data into two streams. Inverse Fast Fourier Transform (IFFT) processing, and time domain processing, may be done on each stream separately. The streams may be mapped on to the two 80 MHz channels, and the data may be transmitted by a transmitting STA. At the receiver of the receiving STA, the above described operation for the 80+80 configuration may be reversed, and the combined data may be sent to the Medium Access Control (MAC).

Sub 1 GHz modes of operation are supported by 802.11af and 802.11ah. The channel operating bandwidths, and carriers, are reduced in 802.11af and 802.11ah relative to those used in 802.11n, and 802.11ac. 802.11af supports 5 MHz, 10 MHZ, and 20 MHz bandwidths in the TV White Space (TVWS) spectrum, and 802.11ah supports 1 MHZ, 2 MHZ, 4 MHZ, 8 MHz, and 16 MHz bandwidths using non-TVWS spectrum. According to a representative embodiment, 802.11ah may support Meter Type Control/Machine-Type Communications, such as MTC devices in a macro coverage area. MTC devices may have certain capabilities, for example, limited capabilities including support for (e.g., only support for) certain and/or limited bandwidths. The MTC devices may include a battery with a battery life above a threshold (e.g., to maintain a very long battery life).

WLAN systems, which may support multiple channels, and channel bandwidths, such as 802.11n, 802.11ac, 802.11af, and 802.11ah, include a channel which may be designated as the primary channel. The primary channel may have a bandwidth equal to the largest common operating bandwidth supported by all STAs in the BSS. The bandwidth of the primary channel may be set and/or limited by a STA, from among all STAs in operating in a BSS, which supports the smallest bandwidth operating mode. In the example of 802.11ah, the primary channel may be 1 MHz wide for STAs (e.g., MTC type devices) that support (e.g., only support) a 1 MHz mode, even if the AP, and other STAs in the BSS support 2 MHZ, 4 MHZ, 8 MHZ, 16 MHZ, and/or other channel bandwidth operating modes. Carrier sensing and/or Network Allocation Vector (NAV) settings may depend on the status of the primary channel. If the primary channel is busy, for example, due to a STA (which supports only a 1 MHz operating mode), transmitting to the AP, the entire available frequency bands may be considered busy even though a majority of the frequency bands remains idle and may be available.

In the United States, the available frequency bands, which may be used by 802.11ah, are from 902 MHz to 928 MHz. In Korea, the available frequency bands are from 917.5 MHz to 923.5 MHz. In Japan, the available frequency bands are from 916.5 MHz to 927.5 MHz. The total bandwidth available for 802.11ah is 6 MHz to 26 MHz depending on the country code.

FIG. 1D is a system diagram illustrating the RAN 113 and the CN 115 according to an embodiment. As noted above, the RAN 113 may employ an NR radio technology to communicate with the WTRUs 102a, 102b, 102c over the air interface 116. The RAN 113 may also be in communication with the CN 115.

The RAN 113 may include gNBs 180a, 180b, 180c, though it will be appreciated that the RAN 113 may include any number of gNBs while remaining consistent with an embodiment. The gNBs 180a, 180b, 180c may each include one or more transceivers for communicating with the WTRUs 102a, 102b, 102c over the air interface 116. In one embodiment, the gNBs 180a, 180b, 180c may implement MIMO technology. For example, gNBs 180a, 108b may utilize beamforming to transmit signals to and/or receive signals from the gNBs 180a, 180b, 180c. Thus, the gNB 180a, for example, may use multiple antennas to transmit wireless signals to, and/or receive wireless signals from, the WTRU 102a. In an embodiment, the gNBs 180a, 180b, 180c may implement carrier aggregation technology. For example, the gNB 180a may transmit multiple component carriers to the WTRU 102a (not shown). A subset of these component carriers may be on unlicensed spectrum while the remaining component carriers may be on licensed spectrum. In an embodiment, the gNBs 180a, 180b, 180c may implement Coordinated Multi-Point (COMP) technology. For example, WTRU 102a may receive coordinated transmissions from gNB 180a and gNB 180b (and/or gNB 180c).

The WTRUs 102a, 102b, 102c may communicate with gNBs 180a, 180b, 180c using transmissions associated with a scalable numerology. For example, the OFDM symbol spacing and/or OFDM subcarrier spacing may vary for different transmissions, different cells, and/or different portions of the wireless transmission spectrum. The WTRUs 102a, 102b, 102c may communicate with gNBs 180a, 180b, 180c using subframe or transmission time intervals (TTIs) of various or scalable lengths (e.g., containing varying number of OFDM symbols and/or lasting varying lengths of absolute time).

The gNBs 180a, 180b, 180c may be configured to communicate with the WTRUs 102a, 102b, 102c in a standalone configuration and/or a non-standalone configuration. In the standalone configuration, WTRUs 102a, 102b, 102c may communicate with gNBs 180a, 180b, 180c without also accessing other RANs (e.g., such as eNode-Bs 160a, 160b, 160c). In the standalone configuration, WTRUs 102a, 102b, 102c may utilize one or more of gNBs 180a, 180b, 180c as a mobility anchor point. In the standalone configuration, WTRUs 102a, 102b, 102c may communicate with gNBs 180a, 180b, 180c using signals in an unlicensed band. In a non-standalone configuration WTRUs 102a, 102b, 102c may communicate with/connect to gNBs 180a, 180b, 180c while also communicating with/connecting to another RAN such as eNode-Bs 160a, 160b, 160c. For example, WTRUs 102a, 102b, 102c may implement DC principles to communicate with one or more gNBs 180a, 180b, 180c and one or more eNode-Bs 160a, 160b, 160c substantially simultaneously. In the non-standalone configuration, eNode-Bs 160a, 160b, 160c may serve as a mobility anchor for WTRUs 102a, 102b, 102c and gNBs 180a, 180b, 180c may provide additional coverage and/or throughput for servicing WTRUs 102a, 102b, 102c.

Each of the gNBs 180a, 180b, 180c may be associated with a particular cell (not shown) and may be configured to handle radio resource management decisions, handover decisions, scheduling of users in the UL and/or DL, support of network slicing, dual connectivity, interworking between NR and E-UTRA, routing of user plane data towards User Plane Function (UPF) 184a, 184b, routing of control plane information towards Access and Mobility Management Function (AMF) 182a, 182b and the like. As shown in FIG. 1D, the gNBs 180a, 180b, 180c may communicate with one another over an Xn interface.

The CN 115 shown in FIG. 1D may include at least one AMF 182a, 182b, at least one UPF 184a, 184b, at least one Session Management Function (SMF) 183a, 183b, and possibly a Data Network (DN) 185a, 185b. While each of the foregoing elements are depicted as part of the CN 115, it will be appreciated that any of these elements may be owned and/or operated by an entity other than the CN operator.

The AMF 182a, 182b may be connected to one or more of the gNBs 180a, 180b, 180c in the RAN 113 via an N2 interface and may serve as a control node. For example, the AMF 182a, 182b may be responsible for authenticating users of the WTRUs 102a, 102b, 102c, support for network slicing (e.g., handling of different PDU sessions with different requirements), selecting a particular SMF 183a, 183b, management of the registration area, termination of NAS signaling, mobility management, and the like. Network slicing may be used by the AMF 182a, 182b in order to customize CN support for WTRUs 102a, 102b, 102c based on the types of services being utilized WTRUs 102a, 102b, 102c. For example, different network slices may be established for different use cases such as services relying on ultra-reliable low latency (URLLC) access, services relying on enhanced massive mobile broadband (eMBB) access, services for machine type communication (MTC) access, and/or the like. The AMF 162 may provide a control plane function for switching between the RAN 113 and other RANs (not shown) that employ other radio technologies, such as LTE, LTE-A, LTE-A Pro, and/or non-3GPP access technologies such as WiFi.

The SMF 183a, 183b may be connected to an AMF 182a, 182b in the CN 115 via an N11 interface. The SMF 183a, 183b may also be connected to a UPF 184a, 184b in the CN 115 via an N4 interface. The SMF 183a, 183b may select and control the UPF 184a, 184b and configure the routing of traffic through the UPF 184a, 184b. The SMF 183a, 183b may perform other functions, such as managing and allocating UE IP address, managing PDU sessions, controlling policy enforcement and QoS, providing downlink data notifications, and the like. A PDU session type may be IP-based, non-IP based, Ethernet-based, and the like.

The UPF 184a, 184b may be connected to one or more of the gNBs 180a, 180b, 180c in the RAN 113 via an N3 interface, which may provide the WTRUs 102a, 102b, 102c with access to packet-switched networks, such as the Internet 110, to facilitate communications between the WTRUs 102a, 102b, 102c and IP-enabled devices. The UPF 184, 184b may perform other functions, such as routing and forwarding packets, enforcing user plane policies, supporting multi-homed PDU sessions, handling user plane QoS, buffering downlink packets, providing mobility anchoring, and the like.

The CN 115 may facilitate communications with other networks. For example, the CN 115 may include, or may communicate with, an IP gateway (e.g., an IP multimedia subsystem (IMS) server) that serves as an interface between the CN 115 and the PSTN 108. In addition, the CN 115 may provide the WTRUs 102a, 102b, 102c with access to the other networks 112, which may include other wired and/or wireless networks that are owned and/or operated by other service providers. In one embodiment, the WTRUs 102a, 102b, 102c may be connected to a local Data Network (DN) 185a, 185b through the UPF 184a, 184b via the N3 interface to the UPF 184a, 184b and an N6 interface between the UPF 184a, 184b and the DN 185a, 185b.

In view of FIGS. 1A-1D, and the corresponding description of FIGS. 1A-1D, one or more, or all, of the functions described herein with regard to one or more of: WTRU 102a-d, Base Station 114a-b, eNode-B 160a-c, MME 162, SGW 164, PGW 166, gNB 180a-c, AMF 182a-b, UPF 184a-b, SMF 183a-b, DN 185a-b, and/or any other device(s) described herein, may be performed by one or more emulation devices (not shown). The emulation devices may be one or more devices configured to emulate one or more, or all, of the functions described herein. For example, the emulation devices may be used to test other devices and/or to simulate network and/or WTRU functions.

The emulation devices may be designed to implement one or more tests of other devices in a lab environment and/or in an operator network environment. For example, the one or more emulation devices may perform the one or more, or all, functions while being fully or partially implemented and/or deployed as part of a wired and/or wireless communication network in order to test other devices within the communication network. The one or more emulation devices may perform the one or more, or all, functions while being temporarily implemented/deployed as part of a wired and/or wireless communication network. The emulation device may be directly coupled to another device for purposes of testing and/or may performing testing using over-the-air wireless communications.

The one or more emulation devices may perform the one or more, including all, functions while not being implemented/deployed as part of a wired and/or wireless communication network. For example, the emulation devices may be utilized in a testing scenario in a testing laboratory and/or a non-deployed (e.g., testing) wired and/or wireless communication network in order to implement testing of one or more components. The one or more emulation devices may be test equipment. Direct RF coupling and/or wireless communications via RF circuitry (e.g., which may include one or more antennas) may be used by the emulation devices to transmit and/or receive data.

Reference to a timer herein may refer to a time, a time period, tracking the time, tracking the period of time, etc. Reference to a timer expiration herein may refer to determining that the time has occurred or that the period of time has expired.

Machine Learning (ML)-based approaches to reduce the channel state information (CSI) overhead in multiple input multiple output (MIMO)/Massive MIMO systems (e.g., which may be referred to as CSI compression) are emerging. While the ML-based CSI compression approaches may have the potential to reduce the overhead and improve the CSI quality, such approaches may result in increased WTRU complexity. The neural network (NN) encoders used to compress the CSI at a WTRU (e.g., a WTRU side) may have computational and/or memory requirements, for example, which may lead to increased latency and/or power consumption.

Some approaches for CSI compression may use a fixed size for the NN encoder models (e.g., fixed input and/or output size and/or fixed compression ratio), and as a result may have a limited ability to support variable CSI sizes to account for different numbers of antennas and/or different bandwidths. Other approaches, for example, which may be based on a convolutional NN, may offer more flexibility to different input CSI sizes, but may increase encoder complexity.

Feature(s) associated with reducing the complexity and/or latency of the NN encoders used for CSI compression and supporting different number of antennas as well as different bandwidth configurations are provided.

For artificial intelligence (AI)/ML capable WTRUs configured for AI/ML-based CSI compression, the WTRU complexity may be reduced by using a smaller data processing model (e.g., AI NN encoder model or AI NN encoder). To support a broad range of configurations (e.g., different bandwidth configurations), the WTRU may select to pre-process the CSI measurement(s) submitted to the AI NN encoder input, e.g., as a function of one or more channel condition(s). For example, the WTRU may determine one or more channel condition(s) associated with pre-processing (e.g., used in selecting a pre-processing type) and select a pre-processing type based, at least in part, on the channel condition(s). The channel condition associated with pre-processing may be determined based on a value of a channel measurement parameter (e.g., a threshold). In order for the gNB to restore the CSI measured by the WTRU, the gNB may require information on the pre-processing configuration and/or information on the Al NN encoder.

Channel condition(s) may also be referred to as “channel characteristic(s)” and “characteristic channel feature(s).” Channel condition(s) may include, for example, channel coherence time, channel coherence bandwidth, Doppler spread, indoor or outdoor deployment, static or mobile scenario, etc.

One or more of the following may apply: techniques to determine the pre-processing type to be applied to the CSI measurements, for example, before compression using an AI NN encoder; techniques to handle different CSI sizes if the WTRU is configured with a fixed size AI NN encoder; techniques to determine the pre-processing type and the AI NN encoder as a function of channel condition(s) (e.g., based on one or more determined channel condition(s) associated with pre-processing) and configured data processing model(s) (e.g., encoder(s)), for example, to meet CSI size and/or compression performance targets; or techniques to indicate the determined pre-processing type and/or the AI NN encoder.

Example multi-dimensional pre-processing techniques are provided herein. A WTRU may apply pre-processing in one or more of the following dimensions (e.g., domains): time, frequency, angle-delay, or spatial (e.g., via Tx and/or Rx antennas). The WTRU may not apply pre-processing (e.g., may not select a pre-processing type). The WTRU may determine the dimensions on which to perform pre-processing and the order of the pre-processing. Example extended WTRU reporting for channel parameters, time-domain pre-processing, frequency-domain pre-processing, angle-delay domain pre-processing, and/or spatial-domain pre-processing are provided herein.

A WTRU may be configured to perform Al/ML-based CSI compression for CSI feedback reporting. The WTRU may be configured with one or more pre-processing types (e.g., frequency-domain, angle-delay domain, time-domain, and/or spatial-domain) and/or one or more pre-processing parameters. The WTRU may be configured with parameters associated with one or more AI NN encoders (e.g., encoder type, input size, layer information, compression rate, model training information, and/or the like). The WTRU may be configured with the CSI report size and/or quality.

The WTRU may perform measurements for the supported pre-processing types (e.g., pre-processing types supported by a data processing model of the WTRU). In examples, for frequency domain pre-processing, the WTRU may perform measurements to determine the channel coherence bandwidth (BW) and may determine the number of CSI (e.g., channel frequency response (CFR) samples that may be averaged (e.g., or down-sampled) in a frequency domain. For angle-delay domain pre-processing, the WTRU may perform measurements to determine the delay spread of the channel and may use the measured delay spread to select the significant rows (e.g., corresponding to delays) of the angle-delay domain CSI. For spatial-domain pre-processing, the WTRU may perform measurements to determine the spatial correlation among antenna elements. For example, the WTRU may determine if antennas may be average and/or how many antennas may be averaged, e.g., to reduce the CSI dimensionality at the AI NN encoder input. For time domain pre-processing (e.g., for recurrent neural network (RNN)-based AI NN encoders), the WTRU may use the age of the samples to reduce input dimensionality, for example, by using one or more windows, where one or more windows (e.g., each window) may use one or more down-sampling rates (e.g., or may use averaging lengths).

Feature(s) associated with an AI NN encoder supporting multiple input sizes are provided. The WTRU may be configured with a data processing model (e.g., an AI NN encoder model; e.g., one AI NN encoder model), for example, an AI NN encoder with input dimension (Kₑ×Nₑ×Mₑ). The link configuration may change (e.g., may be dynamic or semi-static) and the corresponding CSI may not match the AI NN encoder size. The WTRU may use the same data processing model multiple times by splitting the input dimension to fit the configured Al model input dimension (e.g., when the input dimensions are larger than the configured AI NN encoder input size). An AI NN encoder may be configured to support multiple input sizes, e.g., by defining a joint loss function for the multiple-input-multiple output autoencoder (AE) and by jointly training the AE across the multiple inputs/multiple outputs.

Techniques to determine the pre-processing type may be provided. A WTRU may be configured with a set of reference AI NN encoders and may support multiple pre-processing types. The WTRU may perform CSI measurements and may perform channel measurements, for example, to determine the pre-processing type. A WTRU may be configured with a set of reference AI NN encoders and/or one or more pre-processing types. The WTRU may be configured for a CSI report size. The WTRU may determine the pre-processing type and/or the AI NN encoder model, e.g., based on the channel characteristic(s) and/or the configured CSI report size (e.g., and/or quality).

In the case where a WTRU performs CSI measurements and performs channel measurements to determine the pre-processing type, one or more of the following may apply: the WTRU may calculate the CSI size when a first pre-processing type is used; the WTRU may calculate the CSI size when a second pre-processing type is used; the WTRU may select the pre-processing type that results in the smaller CSI size; when the WTRU selects the pre-processing type (e.g., autonomously selects the pre-processing type), the WTRU may pre-process the CSI using the selected pre-processing type, may compress the pre-processed CSI using the compatible AI NN encoder, and may report (e.g., send an indication of) the selected pre-processing type/parameters to the gNB; and/or when a network (NW) selects the pre-processing type (e.g., NW-controlled pre-processing type selection), the WTRU may signal a preferred pre-processing type and an associated AI NN encoder to the gNB.

When a WTRU determines the pre-processing type and the AI NN encoder model, e.g., based on the channel characteristics and the configured CSI report size (e.g., and/or quality), one or more of the following may apply. The WTRU may determine that one or more combinations of AI NN encoder model(s) and pre-processing type(s) meets the CSI report size. The WTRU may select the preferred pre-processing type and AI NN model, for example, so that the CSI compression quality metric exceeds the configured threshold. In examples, if more than one combination of pre-processing type and AI NN models achieves the CSI compression quality metric and/or the maximum number of allocated bits for the CSI report, the WTRU may choose a combination of pre-processing type and AI NN model to optimize one or more of criteria such as, for example, the value of the achieved compression quality metric, processing time, memory requirements, etc. The WTRU may pre-process the channel measurement, for example, using the selected pre-processing type. The WTRU may compress the pre-processed channel matrix (e.g., the compressed CSI) using the configured/selected AI/ML NN encoder. The WTRU may report the parameters of the selected pre-processing type and AI NN encoder model. The WTRU may report the compressed CSI.

Feature(s) associated with indicating the pre-processing type are provided.

Feature(s) associated with CSI reporting are provided. CSI may include one or more of the following: channel quality index (CQI); rank indicator (RI); precoding matrix index (PMI); a Layer1 (L1) channel measurement (e.g., reference signal received power (RSRP) such as L1-RSRP or signal to interference and noise ratio (SINR)); CSI-RS resource indicator (CRI); synchronization signal/physical broadcast channel (SS/PBCH) block resource indicator (SSBRI); layer indicator (LI); or any other measurement quantity measured by the WTRU from the configured reference signals (e.g., CSI-RS, SS/PBCH block, or any other reference signal).

Example CSI reporting framework(s) are provided. A WTRU may be configured to report the CSI, for example, via the uplink control channel on physical uplink control channel (PUCCH) or per the gNBs' request on an uplink (UL) physical uplink shared channel (PUSCH) grant. Based on the configuration, CSI-RS may cover the full bandwidth of a Bandwidth Part (BWP) or may cover a fraction of it. Within the CSI-RS bandwidth, the CSI-RS may be configured for each physical resource block (PRB) or for every other PRBs (e.g., alternative PRBs). In the time domain, CSI-RS resources may be (e.g., may be configured to be) periodic, semi-persistent, or aperiodic. Semi-persistent CSI-RS may be similar to periodic CSI-RS, except that the resource may be deactivated or activated by MAC CEs and the WTRU may report related measurements when (e.g., only when) the resource is activated. For aperiodic CSI-RS, the WTRU may be triggered to report measured CSI-RS on PUSCH by a request via downlink control information (DCI). Periodic reports may be carried via PUCCH, while semi-persistent reports may be carried via PUCCH or PUSCH. The reported CSI may be used by the scheduler when allocating optimal resource blocks, for example, based on the channel's time-frequency selectivity, determining precoding matrices, beams, transmission mode, and selecting suitable modulation and coding schemes (MCSs). The reliability, accuracy, and/or timeliness of WTRU CSI reports may be involved in meeting ultra-reliable and low latency communications (URLLC) service requirements.

A WTRU may be configured with a CSI measurement setting, which may include, for example, one or more CSI reporting settings, resource settings, and/or a link between one or more CSI reporting settings and one or more resource settings.

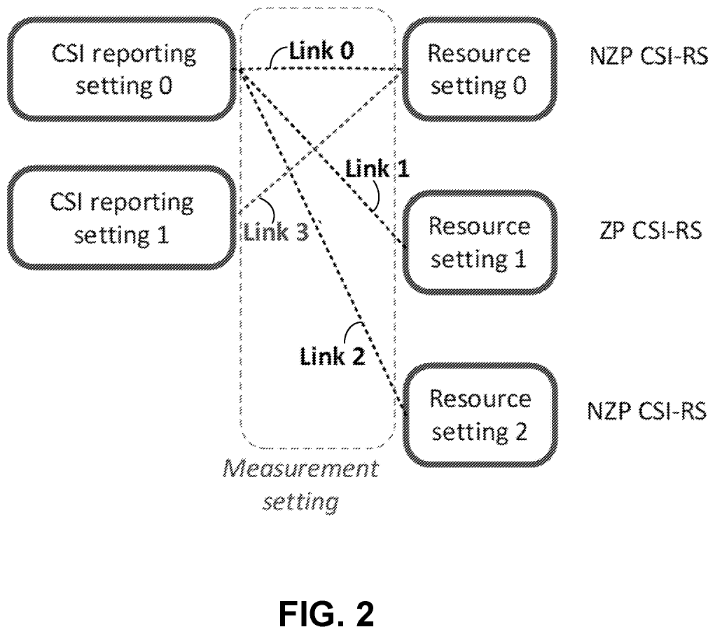

FIG. 2 shows an example of a CSI measurement setting. FIG. 2 shows an example configuration for CSI reporting settings, resource settings, and the link.

For a CSI measurement setting, one or more of the following configuration parameters may be provided. The configuration parameters may include N>1 CSI reporting settings, M≥1 resource settings, and a CSI measurement setting which links the N CSI reporting settings with the M resource settings. The configuration parameters may include a CSI reporting setting, which may include, for example, one or more of the following: time-domain behavior (e.g., aperiodic or periodic/semi-persistent); frequency-granularity (e.g., at least for PMI and CQI); CSI reporting type (e.g., PMI, CQI, RI, CRI, etc.); or if a PMI is reported, PMI Type (e.g., Type I or II) and codebook configuration. The configuration parameters may include a resource setting, for example, which may include one or more of the following: time-domain behavior (e.g., aperiodic or periodic/semi-persistent); RS type (e.g., for channel measurement or interference measurement); or S≥1 resource set(s) and each resource set may include Ks resources. The configuration parameters may include a CSI measurement setting which may include one or more of the following: a CSI reporting setting; a resource setting; or for CQI, a reference transmission scheme setting. The configuration parameters may include the following. For CSI reporting for a component carrier, one or more of the following frequency granularities may be supported: wideband CSI, partial band CSI, or Sub-band CSI.

Codebook-based precoding may be provided.

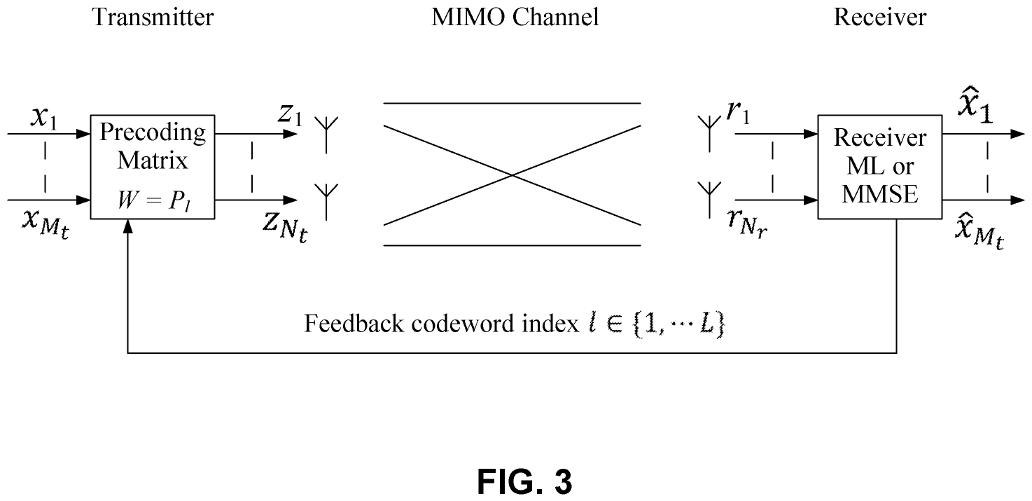

FIG. 3 shows an example of codebook-based precoding with feedback information. In FIG. 3, an example of codebook-based precoding with feedback information may be provided. The feedback information may include a PMI which may be referred to as a codeword index in the codebook as shown with respect to FIG. 3.

As shown with respect to FIG. 3, a codebook may include a set of precoding vectors/matrices for one or more ranks (e.g., each rank) and the number of antenna ports, and one or more precoding vectors/matrices (e.g., each of the precoding vectors/matrices) may have its own index, for example, so that a receiver may inform preferred precoding vector/matrix index to a transmitter. The codebook-based precoding may have performance degradation due to its finite number of precoding vector/matrix as compared with non-codebook-based precoding. A codebook-based precoding may be associated with lower control signaling/feedback overhead. Table 1 shows an example of codebook for 2Tx.

TABLE 1
2Tx downlink codebook

| Codebook | Number of rank | |
|---|---|---|
| index | 1 | 2 |
| 0 | $\frac{1}{\sqrt{2}} [ \begin{matrix}1 \\ 1\end{matrix} ]$ | $\frac{1}{\sqrt{2}} [ \begin{matrix}1 & 0 \\ 0 & 1\end{matrix} ]$ |
| 1 | $\frac{1}{\sqrt{2}} [ \begin{matrix}1 \\ - 1\end{matrix} ]$ | $\frac{1}{2} [ \begin{matrix}1 & 1 \\ 1 & - 1\end{matrix} ]$ |
| 2 | $\frac{1}{\sqrt{2}} [ \begin{matrix}1 \\ j\end{matrix} ]$ | $\frac{1}{2} [ \begin{matrix}1 & 1 \\ j & - j\end{matrix} ]$ |
| 3 | $\frac{1}{\sqrt{2}} [ \begin{matrix}1 \\ - j\end{matrix} ]$ | — |

Feature(s) associated with CSI processing criteria are provided. A CSI processing unit (CPU) may be referred to as a minimum CSI processing unit and a WTRU may support one or more CPUs (e.g., N CPUs). A WTRU with N CPUs may estimate N CSI feedbacks calculation in parallel and N may be associated with WTRU capability. In examples, if a WTRU is requested to estimate more than N CSI feedbacks at the same time, the WTRU may perform (e.g., only perform) high priority N CSI feedbacks and the rest may be not estimated.

The start and end of a CPU may be determined based on the CSI report type (e.g., aperiodic, periodic, or semi-persistent) as following. For an aperiodic CSI report, a CPU may start to be occupied from the first orthogonal frequency-division multiplexing (OFDM) symbol after the PDCCH trigger until the last OFDM symbol of the PUSCH carrying the CSI report. For a periodic and semi-persistent CSI report, a CPU may start to be occupied from the first OFDM symbol of one or more associated measurement resources (e.g., not earlier than CSI reference resource) until the last OFDM symbol of the CSI report.

The number of CPUs occupied may be different based on the CSI measurement types (e.g., beam-based or non-beam based) as following: non-beam related reports (e.g., Ks CPUs when Ks CSI-RS resources in the CSI-RS resource set for channel measurement); beam-related reports (e.g., “cri-RSRP,” “ssb-Index-RSRP,” or “none”) (e.g., one CPU may be used irrespective of the number of CSI-RS resource in the CSI-RS resource set for channel measurement due to the CSI computation complexity being low, and “None” may be used for P3 (e.g., downlink beam refinement procedure) operation or aperiodic Tracking Reference Signal (TRS) transmission); for an aperiodic CSI reporting with a single CSI-RS resource, one CPU may be occupied; or for a CSI reporting Ks CSI-RS resources, Ks CPUs may be occupied as the WTRU needs to perform CSI measurement for each CSI-RS resource.

When the number of unoccupied CPUs (e.g., Nᵤ) is less than a threshold number of (e.g., a required number of) CPUs (e.g., Nᵣ) for CSI reporting, one or more of the following WTRU behavior may be used: the WTRU may drop Nᵣ-Nᵤ CSI reporting based on priorities in the case of UCI on PUSCH without data/HARQ or the WTRU may (e.g., in other cases) report dummy information in Nᵣ-Nᵤ CSI reporting based on priorities to avoid rate-matching handling of PUSCH.

Feature(s) associated with Al/ML-based CSI compression are provided. A class of AI/ML-based CSI compression may include unsupervised learning based on AEs. The WTRU may use an AI NN encoder to compress the CSI according to a given compression ratio. The WTRU may feed the compressed CSI back to the gNB. The gNB may perform the inverse operation using an AI NN decoder to reconstruct the original CSI from the received compressed CSI. The AI NN encoder and decoder of an autoencoder may be jointly trained.

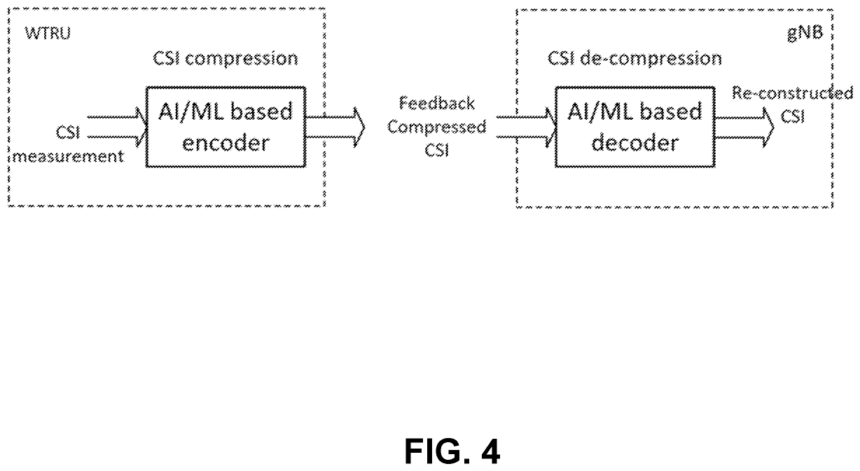

FIG. 4 shows an example of AEs for CSI compression. FIG. 4 illustrates an example AE-based approach to CSI compression for wireless systems.

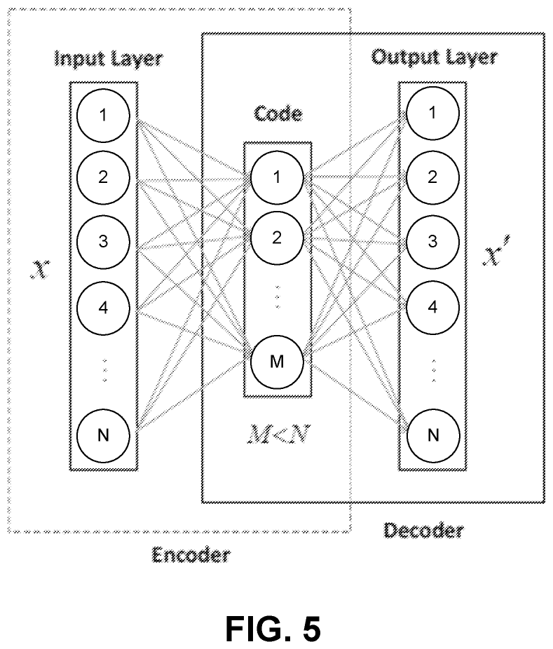

FIG. 5 shows an example of a block diagram of an AE.

The compression ratio of the AI NN encoder may be defined as the ratio between the size of the encoder output (e.g., denoted by “M” in FIG. 5) and the size at the encoder input (denoted by “N” in FIG. 5).

In examples, for AI/ML-based CSI compression in MIMO systems, the channel response matrix estimated by the WTRU may be applied at the input of the AI/ML NN encoder. A frequency-domain sample of the channel response may be a complex-valued matrix of size (Nr×Nt), where Nr may be the number of receive antennas at the WTRU and Nt may be the number of Tx antenna ports at the gNB. The CSI feedback may report Nc frequency domain samples of the channel response, where based on the reporting granularity, Nc may refer to the number of sub-carriers, resource block (RB), or sub-bands used for CSI feedback. The size of the channel response matrix (e.g., before pre-processing and/or compression) may be Nc×Nr×Nt complex values. For MIMO systems with a large number of Tx and Rx antennas, the total size of the channel matrix to be (e.g., that needs to be) compressed may become large, which may, for example, result in large NN model sizes.

A way to reduce the AI NN model size may be to pre-process the CSI measurement, for example, prior to the compression.

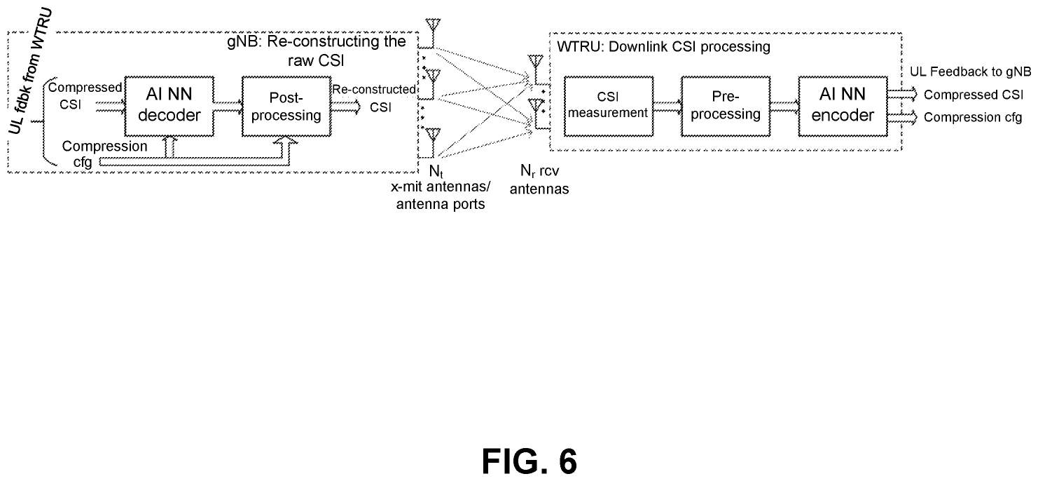

FIG. 6 illustrates an example of AEs for CSI compression with pre-processing at the AI NN encoder input. The pre-processing of the CSI measurements, the Al NN-based compression at the WTRU, and the corresponding processing at the gNB are illustrated in FIG. 6.

The pre-processing may be a linear transformation that converts the channel response matrix from the space-frequency domain to the angle-delay domain. In the angle-delay domain, the channel response matrices of MIMO systems may be sparse. The transformation to angle-delay domain may be achieved via a 2-D discrete Fourier transform (DFT), as shown below:

H=F₁ĤF₂

For a system with Nt transmit antennas, Nc frequency domain samples, and Nr=1 receive antennas:

A may represent the channel matrix (e.g., estimated by the WTRU) in the space-frequency domain. It may be a complex matrix of size Nc×Nt;
F₁ may be the DFT matrix of size Nc×Nc;
F₂ may be the DFT matrix of size Nt×Nt; and
H may be the channel response matrix in the angle-delay domain. The channel response matrix may be a complex matrix of size Nc×Nt.

Since the matrix is sparse in the angle-delay domain, the size of the matrix may be reduced by truncating to Nc′ rows that include non-zero elements, where Nc′<Nc.

Although pre-processing using the 2-D DFT transform as described herein reduces the size of the channel matrix at the AI NN encoder input, multiple AI NN encoder models may be used (e.g., may be required) to support different configurations (e.g., number of Tx and Rx antennas, different bandwidth configurations and reporting granularities, etc.).

Autoencoders may be based on deep neural networks (DNN), convolutional neural networks (CNN), and/or recurrent neural networks (RNN).

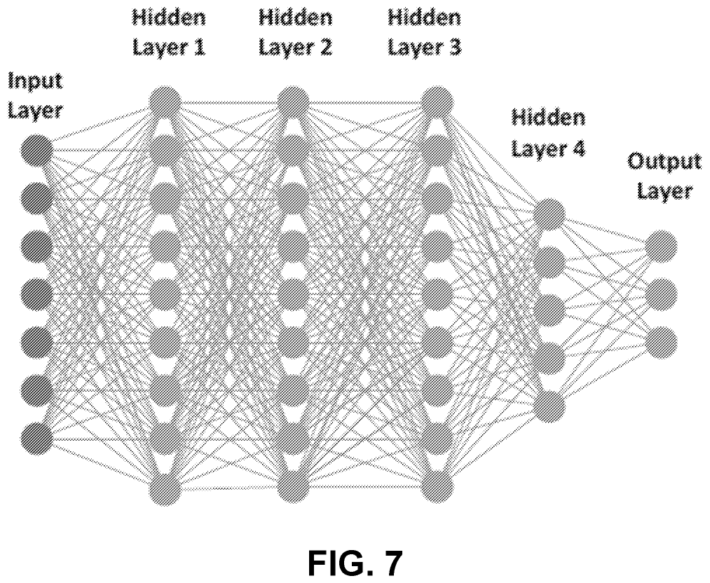

FIG. 7 is a block diagram of an example DNN.

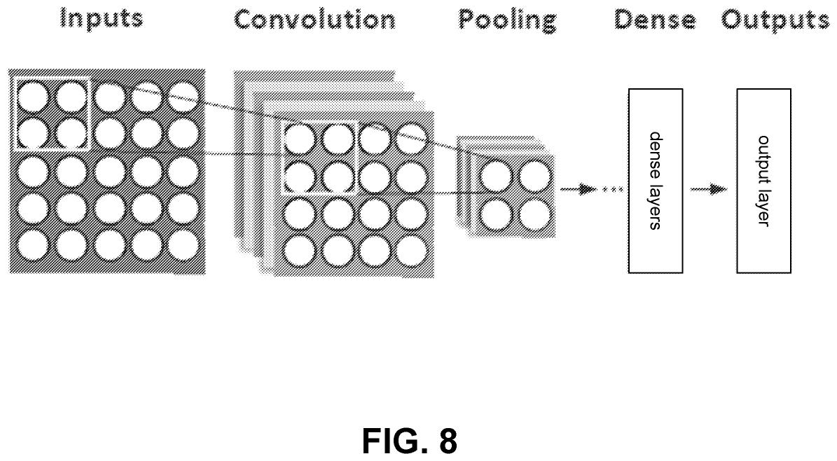

FIG. 8 is a block diagram of an example CNN.

AI NN encoders may include a layered architecture that may include, for example, multiple fully connected and/or convolutional layers, and/or pooling and batch normalization layers. The AI NN decoders may include multiple fully-connected and/or convolutional layers, and/or pooling and batch normalization layers. The AI NN encoders may be characterized by the NN model architecture and one or more parameters such as the compression ratio, length, width and number of feature maps. The parameters may need to be known at the gNB, for example, so that the AI NN decoder can reconstruct the CSI estimated by the WTRU.

Larger NN models may tend to provide better compression performance at the expense of higher complexity (e.g., computational and memory requirements), increased power consumption, and/or processing latency.

AI encoder, AI NN encoder, AI/ML NN encoder, Al model, NN model, or similar combinations may be used interchangeably herein.

The term Al model may correspond to an AI encoder or decoder, an AI NN encoder or decoder, or an Al/ML encoder or decoder and may be used interchangeably herein.

CSI reporting may be a component of MIMO systems. System performance may be impacted by the quality and timeliness of the CSI reports and/or by the overhead associated with CSI reporting. With the proliferation of small cells, emergence of distributed MIMO systems, as well as migration to higher frequency bands, the number of antennas at gNBs (e.g., base stations) and/or WTRUs (e.g., mobile terminals) may keep increasing, which may result in CSI feedback overhead (e.g., excessive CSI feedback overhead) and lead to loss in performance.

Feature(s) associated with pre-processing for CSI compression in wireless systems are provided. An ML-capable WTRU may be configured for Al/ML autoencoder-based CSI feedback.

The WTRU may determine to pre-process the CSI measurements submitted to the AE input, e.g., as a function of the channel conditions. The WTRU may use measurements (e.g., channel measurements), for example, to reduce the dimensionality at the AE input and/or reduce the CSI processing latency. The WTRU may report to the gNB a selected pre-processing configuration, e.g., to enable the recovery of the uncompressed CSI at the gNB.

Example pre-processing types are provided. Pre-processing type may refer to processing (e.g., any processing) the WTRU may apply to the CSI measurements, e.g., prior to the compression by a data processing model (e.g., an AI NN encoder, which may be used as an example herein). Examples of pre-processing types may include one or more of the following: frequency domain; time domain; spatial domain; or linear transformation of the channel matrix H, for example, to convert to the angular-delay domain.

Pre-processing type or types of pre-processing may be used interchangeably herein.

An example channel response matrix is provided. A channel frequency response (CFR) matrix estimated by the WTRU in the space-frequency domain may be denoted by Ĥ. It may be a 3-D matrix (e.g., a complex 3-D matrix) of size Nc×N_{R}×N_{T}, where Nc may represent the number of samples in the frequency domain, N_{R} may represent the number of receive antennas, and N_{T} may represent the number of Tx antennas/antenna ports.

The examples described herein for selecting the pre-processing type and/or the AI NN encoder may apply to the compression of the CFR. Techniques described herein may be applicable to interference measurements including, for example, implicit CSI measurements.

Example CSI compression/reconstruction metrics are provided. The normalized mean squared error (NMSE) may be used to assess the quality of the CSI compression and/or reconstruction. The NMSE may be defined as:

$$NMSE = E \{ {‖ H - \tilde{H} ‖}_{F}^{2} / {‖ H ‖}_{F}^{2} \}$$

where H may represent the CSI matrix (e.g., channel response matrix) at an input of the AI NN encoder, \tilde{H} may represent the reconstructed matrix at an output of the AI NN decoder, and the operator ∥ ∥_{F} may indicate the Frobenius (e.g., Euclidean) norm.

An example measure of the quality of the CSI compression and/or reconstruction is cosine similarity, ρ. The cosine similarity may be represented by the equation:

$$ρ = E \{ \frac{1}{{N}_{c}} {\sum }_{n = 1}^{{N}_{c}} \frac{\vert {\tilde{h}}_{n}^{H} {h}_{n} \vert}{{‖ {\tilde{h}}_{n} ‖}_{2} {‖ {h}_{n} ‖}_{2}} \}$$

where \tilde{h}ₙ may represent the vector on subcarrier “n” of the reconstructed channel matrix, e.g., at the output of the AI NN decoder.

AI encoder, AI NN encoder, and AI/ML NN encoder may be used interchangeably herein. Al decoder, AI NN decoder, and AI/ML NN decoder may be used interchangeably herein.

Example AI NN encoder sizes are provided. AI NN encoder architectures may support 2-D or 3-D input data. The input data size for 2-D AI NN encoder architectures may be denoted herein by (Kₑ×Nₑ), where the subscript “e” may refer to the encoder. The input data size for 3-D AI NN encoder architectures may be denoted herein by (Kₑ×Nₑ×Mₑ).

For AI NN encoders used for CSI compression, the first dimension may refer to the number of frequency domain samples of the CSI array, the second dimension may refer to the number of receive antennas, and the third dimension may refer to the number of transmit (Tx) antennas/antenna ports. In examples, the first dimension may refer to the angle domain (e.g., when DFT is used to transform the CFR to the angle-delay domain).

Examples of information that is pre-processed are provided. The WTRU may pre-process the channel response matrix H (e.g., either the full or the partial channel response matrix). The WTRU may pre-process interference measurements, e.g., based on non-zero power (NZP) CSI-RS.

Feature(s) associated with configuring the pre-processing type are provided. A WTRU may be configured with pre-processor(s), pre-processor type(s), AI NN(s), and/or associated parameters (e.g., parameters associated with each).

An example pre-processing parameter configuration is provided. A WTRU may be configured with one or more pre-processors, pre-processing types, and/or pre-processing techniques. A pre-processing type (e.g., each configured pre-processing type) may be assigned an index. For a pre-processing type, the WTRU may be configured with a set of parameters. In examples, for a pre-processing type, the WTRU may be configured with a value associated with the parameters. One or more of the parameters may be applicable to one or more (e.g., many or all) of the configured pre-processing types. One or more of the parameters may be specific to one pre-processing type.

The configuration of parameters may be done based on a pre-processing type configuration. The configuration of parameters may be done independently of the pre-processing type configuration. For example, a WTRU may be configured with an update of one or more parameter(s) independently of the configuration of the pre-processing type.

A parameter may include a threshold value. The threshold (e.g., threshold value) may be compared to a measurement performed by the WTRU. A parameter may include a dimension and/or a value to be used by the WTRU in the application of the pre-processing type. A parameter may include an element, or the value thereof, of an AI NN encoder. A parameter may include an applicable or associated AI NN encoder (e.g., an AI NN encoder associated with a pre-processing type). A parameter may include a dimension and/or a value to be used by the WTRU in the application of the AI NN encoder.

A WTRU may be configured with a set of parameters (e.g., channel measurement parameters) to be used with one or more pre-processors or pre-processing types, where the set of parameters may include one or more of the following. The set of parameters may include a path power threshold for delay spread calculation. The parameter may be associated with pre-processing types using angle-delay domain pre-processing. A WTRU may compare a path power measurement to the path power threshold. The WTRU may determine whether to include the path in the delay spread calculation (e.g., based on the comparison). The set of parameters may include a channel correlation threshold for coherence BW calculation. The parameter may be associated with pre-processing types using frequency domain pre-processing. A WTRU may compare a channel correlation value to the channel correlation threshold. The WTRU may determine a coherence BW (e.g., based on the comparison). The set of parameters may include a coherence BW threshold. The parameter may be associated with pre-processing types using frequency domain pre-processing. A WTRU may compare a measured coherence BW to the coherence BW threshold. The WTRU may determine whether a channel is flat or frequency-selective (e.g., based on the comparison). For example a measured coherence BW value greater than the coherence BW threshold may indicate a flat fading channel. For example, a measured coherence BW value lower than the coherence BW threshold may indicate a frequency-selective channel. The set of parameters may include a fraction of the coherence BW. The parameter may be associated with pre-processing types using frequency domain pre-processing. The WTRU may use the fraction of the coherence BW, e.g., along with a determined coherence BW, to determine a number of channel samples to average or a down-sampling factor. The set of parameters may include a channel correlation threshold for coherence time calculation. The parameter may be associated with pre-processing types using time domain pre-processing. The WTRU may compare one or more measured channel correlation(s), e.g., obtained at different times, to the channel correlation threshold. The WTRU may determine the coherence time (e.g., based on the comparison). For example, the WTRU may obtain a first channel correlation at a first time and a second channel correlation at a second time. The WTRU may determine a coherence time (e.g., a coherence time value) based on a value of the first channel correlation and a value of the second channel correlation. The set of parameters may include a coherence time threshold. The parameter may be associated with pre-processing types using time domain pre-processing. The WTRU may compare the measured coherence time value to the coherence time threshold. The WTRU may determine whether the channel is slow fading or fast fading (e.g., based on the comparison). For example, a measured coherence time value below the coherence time threshold may indicate a fast fading channel. For example, a measured coherence time value above the coherence time threshold may indicate a slow fading channel. Selection of a pre-processing type may be based, at least in part, on the comparison of the coherence time value to the coherence time threshold.

The set of parameters may include a threshold for spatial domain correlation (e.g., a spatial domain correlation threshold). The parameter may be associated with pre-processing types using spatial domain pre-processing. The WTRU may determine the spatial domain correlation. The WTRU may compare the measured spatial domain correlation to the spatial domain correlation threshold. The WTRU may determine the level of spatial domain correlation (e.g., based on the comparison). Selection of a pre-processing type may be based, at least in part, on the level of spatial domain correlation. The set of parameters may include NN parameter(s), which may include a number of layers, an input dimension, an output dimension, a number of iterations, an input type, an output type, and/or the like. The input type may be associated with a measurement type (e.g., channel measurement, interference measurement, or combined channel and interference measurement). The output type may be the desired CSI feedback report type. The set of parameters may include a pre-processor type. The set of parameters may include pre-processing parameters, which may include the number of inputs and/or outputs of the pre-processor, the quantization of the output, the input type, and/or the output type. The input type and/or the output type may be associated with a measurement type (e.g., channel measurement, interference measurement, or combined channel and interference measurement). The set of parameters may include associated reference signals. For example, a WTRU may be configured with a pre-processor and may be configured with one or more associated RSs (e.g., on which to perform the measurements). The measurement values may be used in determining other parameters of the pre-processor (e.g., via a configurable threshold as described herein).

A WTRU may be configured with one or more parameters, techniques, and/or triggers to enable the selection of a pre-processor or pre-processing type from a set of (e.g., the set includes a plurality of) configured pre-processors or pre-processing types.

Example techniques to determine the pre-processor (e.g., a pre-processing type) to use for a given feedback instance is described herein.

An example configuration of the CSI report size and/or quality is provided. An example feedback report size (e.g., CSI payload that relates to AI NN encoder output dimensions) is provided. A WTRU may be configured with a feedback (e.g., CSI) report size. The feedback report size may indicate one or more of the following: a number of information bits; a number of coded bits; a feedback resource size (e.g., number of symbols or PRBs); and/or a number or content of the feedback report types (e.g., the CSI report size may indicate whether to include RI, CQI, PMI, SINR, channel matrix and/or interference, CSI Type 1, CSI Type 2, and/or the like). The feedback report size may indicate granularity of the feedback report type. For example, the CSI report size may indicate the granularity of one or more feedback report types (e.g., the quantization used to generate a report). The feedback report size may indicate the granularity of the measurements. For example, the CSI report size may indicate the granularity of the measurements. The granularity of the measurements may indicate whether the measurement is wideband, subband, long-term, short-term, averaged over many instances (e.g., in frequency or time), single-shot, etc. The granularity of the measurement may indicate the size (e.g., in PRBs) or duration (e.g., in symbols) of measurements that are not wideband or single-shot.

Quality of the feedback compression may be used for pre-processing and AI NN encoder model selection for a given compression ratio. A WTRU may be configured with a feedback (e.g., CSI) report quality. The feedback report quality may be per feedback report type or for all report types. The feedback report quality may indicate at one or more of the following: the type of compression (e.g., the WTRU may be configured with no compression, lossy compression, or lossless compression); granularity of the compression; and/or amount of acceptable loss due to compression (e.g., which may be measured in number of compressed bits or ratio of compressed bits to information/input bits).

Feature(s) associated with determining a feedback report size and/or compression are provided. A WTRU may determine the feedback report size, e.g., as a function of the smallest (e.g., or largest) feedback report size that achieves a feedback report quality level (e.g., configured feedback report quality level). A WTRU may determine the quality level as the highest (e.g., or lowest) that achieves a feedback report size (e.g., configured feedback report size).

A WTRU may be configured with a feedback report size or feedback report quality per feedback priority level. The WTRU may determine the applicable feedback report size and/or report quality, e.g., as a function of the lowest, highest, or average priority of a feedback report.

A WTRU may determine a feedback report size or quality as a function of the number of feedback report types included in a feedback report. A WTRU may use a first feedback report size and/or feedback report quality for a first feedback report that includes channel matrix and interference. A WTRU may use a second feedback report size and/or feedback report quality for a second feedback report that includes RI/CQI/PMI.

A WTRU may determine a feedback report size and/or a feedback report quality as a function of the size, index, and/or or timing of a feedback report resource.

A WTRU may receive an indication of the feedback report size and/or feedback report quality via a signal (e.g., DCI) requesting a feedback report.

Example configurations of AI NN encoders are provided. Example AI NN encoder capability (ies) are provided. A WTRU may be configured to use one or more different AI NN encoders. The WTRU may be configured with a set of AI NN encoders and may select one or more to use for the generation of a feedback report. The selection of the AI NN encoder(s) may be performed as described herein.

A WTRU may signal an AI NN encoder capability. The capability may indicate whether the WTRU supports a single AI NN encoder or multiple AI NN encoders. The capability may indicate the identity of the supported AI NN encoder(s).

Example AI NN encoder parameters are provided. The WTRU may be configured with parameters associated with one or more AI NN encoders. The parameters may include one or more of the following. The parameters may include an AI NN encoder type. For example, the encoder type may be DNN, CNN, or RNN. The parameters may include an input size. For example, the WTRU may be configured with an input size of Kₑ×Nₑ×Mₑ for a 3-D AI NN architecture. In examples, if the model was trained with frequency-domain CSI, the 1^{st} dimension Kₑ may represent the number of samples in frequency domain (Nc), the 2^{nd} dimension Nₑ may represent the number of Rx antennas (N_{R}), and the 3^{rd} dimension Mₑ may represent the number of Tx antennas/antenna ports (N_{T}). The parameters may include layer information. For example, the layer information may include the number of layers of the model, the type and/or dimensions of a layer (e.g., each layer), and/or the like. The parameters may include the compression rate, for example, whether to use single rate or multi-rate. The parameters may include model training information. For example, the WTRU may be configured with frequency domain training data, angle-delay domain training data, time domain training data, and/or spatial domain training data.

The WTRU may be configured with one or more AI NN encoders, e.g., from the predefined set of reference AI NN encoders. The reference AI NN encoders may achieve a compression quality (e.g., specified compression quality), for example, based on the encoder type, architecture (e.g., number and/or types of layers), and/or compression rate. An example of AI NN encoder performance metrics is shown in Table 2.

TABLE 2
Example AI NN encoder performance metrics table

| AI NN | AI NN | | | | | Cosine |
|---|---|---|---|---|---|---|
| encoder | encoder | Input | Compression | Training | | similarity |
| ID | type | size | rate (CR) | data type | NMSE (dB) | ρ |
| ID1 | DNN/CNN/RNN | Kₑ × | ¼, ⅛, 1/16, | Frequency | NMSE1_dB | Rho1 |
| | | Nₑ × | 1/32, etc. | domain/ | | |
| | | Mₑ | | angle | | |
| | | | | domain | | |
| ID2 | DNN/CNN/RNN | Kₑ × | ¼, ⅛, 1/16, | Frequency | NMSE2_dB | Rho2 |
| | | Nₑ × | 1/32, etc. | domain/ | | |
| | | Mₑ | | angle | | |
| | | | | domain | | |

Feature(s) associated with receiving a configuration are provided. Example signals/channels on which WTRU receives the configuration are provided. A WTRU may receive a configuration for one or more pre-processors, pre-processor types, or AI NN via higher layer signaling. In examples, a WTRU may receive pre-processing configuration via RRC (re) configuration. The RRC (re) configuration may include a set of pre-processors, each associated with a different index.

A WTRU may receive a configuration for one or more pre-processors, pre-processor types, or Al NN via dynamic signaling (e.g., DCI or MAC CE). The dynamic signaling may indicate a parameter or an update of a parameter to use with an associated pre-processor or AI NN.

A WTRU may receive dynamic signaling of a pre-processor or pre-processor type (e.g., specific pre-processor or pre-processor type) to use for one or more feedback reports. A WTRU may receive a feedback report request via DCI. The feedback report request may indicate the pre-processor, pre-processor type, or AI NN to use to generate the feedback report. The indication may be received by the WTRU as a bitfield in the DCI. The bitfield may provide a pre-processor index or AI NN index. The bitfield may provide a set of pre-processor indices or AI NN indices. In such a case, the WTRU may be configured with one or more rules to determine which pre-processor or AI NN to use to generate the feedback report.

A WTRU may receive an indication for a semi-persistent use of a pre-processor, pre-processor type, or AI NN. The indication may be received by the WTRU via a MAC CE. The indication may indicate to the WTRU to use a specific pre-processor, pre-processor type, or AI NN for a set period of time, for a set number of feedback reports, or until further indicated. A WTRU may be expected to provide HARQ-ACK feedback for the indication, for example, before starting to use the semi-persistent pre-processor, pre-processor type, or AI NN.

A WTRU may be configured with one or more set(s) of RSs. The WTRU may be configured with a specific pre-processor or pre-processor type or AI NN for each set of RSs.

Feature(s) associated with reducing the dimensionality at the input of the AI NN encoder are provided. Frequency domain techniques may be used for pre-processing as a function of the channel coherence bandwidth (also sometimes referred to as “coherence bandwidth”). In examples, if the channel coherence bandwidth is above a threshold, the WTRU may down-sample and/or perform averaging to reduce input dimension. If a WTRU (e.g., a data processing model of the WTRU) supports frequency-domain pre-processing, the WTRU may perform measurements to determine the channel coherence bandwidth. If configured, the WTRU may determine the channel coherence bandwidth as the frequency bandwidth for which the channel correlation (e.g., in frequency domain) exceeds the configured threshold. In examples, the WTRU may determine the channel coherence bandwidth as:

$${B}_{c} \approx \frac{1}{5 {τ}_{RMS}}$$

where τ_{RMS} may represent the RMS delay spread of the channel.

The WTRU may determine to use the frequency-domain pre-processing of the CSI, for example, if the channel coherence bandwidth exceeds a configured threshold. The WTRU may determine the number of adjacent CSI-RS REs, denoted nrofHsamp herein, within a fraction of the coherence BW, as a function of the measured coherence BW and configured CSI-RS density. In examples, if the CSI-RS-ResourceMapping density (e.g., expressed in RE/port/PRB) is set to 0.5, 1, or 3, the WTRU may calculate nrofHsamp as:

$$nrofHsamp = ⌊ k \cdot {B}_{c} ( expressed in units of RB ) \cdot CSI - RS - ResourceMapping density ⌋$$

where B_{c} may be the measured coherence BW (e.g., expressed in units of RB), and k may be a configured fraction of the coherence BW (e.g., where k may be configured in the range 0 . . . 1, or k may be set to 1).

In examples, the WTRU may average channel estimates corresponding to nrofHsamp adjacent CSI-RS resources. In examples, the WTRU may down-sample the frequency domain channel estimate by a factor of nrofHsamp.

The CSI size after frequency-domain pre-processing may be (N_{c}×Nᵣ×Nₜ), where N_{c} may represent the number of frequency domain CSI samples after pre-processing (e.g., averaging or down-sampling), Nᵣ may represent the number of receive antennas, and Nₜ may represent the number of configured antenna ports.

N may be calculated as N_{c}=N_{c_total_bwp}/nrofHsamp, where N_{c_total_bwp} may represent the total number of frequency domain samples of the measured channel response across the configured BWP before pre-processing. In examples, N_{c_total_bwp} may be equal to the number of PRB in the configured BWP when the CSI-RS density is 1 (e.g., one CSI-RS per port per PRB). The WTRU may select the frequency-domain pre-processing type, for example, if the AI NN encoder is trained on frequency-domain CSI.

Angle-delay domain techniques may be used for pre-processing as a function of the delay spread of the channel. If the delay spread is below a threshold, the WTRU may do a transformation from frequency domain to angle-delay domain (e.g., to reduce input dimension). If a WTRU (e.g., a data processing model of the WTRU) supports angle-delay domain pre-processing, the WTRU may perform measurements to determine the delay spread of the channel (T). If configured, the WTRU may use the path power threshold for delay spread calculation. In examples, the WTRU may determine the RMS delay spread (τ_RMS).

The WTRU may express the delay spread in number of samples at the current sampling period, Tₛₐₘₚ. The delay spread (e.g., expressed in samples) may be:

$${N}_{d} = \frac{τ}{{T}_{samp}}$$

For example, for NR signals using an FFT size of 2048, the sampling period may be:

$${T}_{samp} = \frac{64}{{2}^{μ}} {T}_{c}$$

where μ may denote the numerology and T_{c} may denote a basic time unit for N_{R}.

The WTRU may measure the channel response matrix, Ĥ, in the frequency domain. When the WTRU performs the measurement based on CSI-RS reference signals, the channel response matrix may need additional processing (e.g., interpolation) to achieve subcarrier resolution. For example, when Nr=1, if N_{sc}^{BWP} denotes the total number of subcarriers per BWP, the measured channel response matrix at subcarrier resolution (e.g., full channel response matrix), Ĥ^{full}, may have the size N_{sc}^{BWP}×Nₜ.

The WTRU may use the full channel response matrix (Ĥ^{full}) to convert to angle-delay domain, as follows:

Hₜₑₘₚ=F₁Ĥ^{full}F₂, where F₁ is the DFT matrix of size N_{sc}^{BWP}×N_{sc}^{BWP}

The WTRU may use the calculated delay spread (e.g., in samples) to truncate the Hₜₑₘₚ matrix by selecting the first significant N_{d} rows.

The WTRU may select the angle-delay domain pre-processing type, for example, if the AI NN encoder is trained on angle-delay domain CSI.

Spatial domain techniques may be provided. In examples, if a WTRU (e.g., a data processing model of the WTRU) supports spatial-domain pre-processing, the WTRU may perform measurements to determine the spatial correlation among one or more antenna elements. If configured to do so, the WTRU may determine the spatial correlation as the number of elements for which the channel correlation (e.g., in the spatial domain) exceeds a (e.g., configured) spatial correlation threshold.

The WTRU may determine to perform spatial-domain pre-processing on the CSI, e.g., prior to feeding it into the CSI compressor. The WTRU may determine the number of adjacent CSI samples that may be averaged in the spatial domain for each CSI matrix.

In examples, the WTRU may partition the channel estimates in each (Nᵣ×Nₜ) matrix into (λᵣ×λₜ) sized blocks and average the coefficients of one or more blocks (e.g., each block) into a single value. The CSI size, (e.g., prior to spatial-domain pre-processing) may be (N_{c}×Nᵣ×Nₜ). The CSI size may converge down to

$$( {N}_{c} \times \frac{{N}_{r}}{{λ}_{r}} \times \frac{{N}_{t}}{{λ}_{t}} )$$

(e.g., alter spatial-domain preprocessing), where N_{c} may represent the number of frequency domain CSI samples, Nᵣ may represent the number of receive antennas, Nₜ may represent the number of configured antenna ports, λᵣ may represent the averaging length in the second dimension of the CSI array (e.g., Rx antennas), and λₜ may represent the averaging length in the third dimension of the CSI array (e.g., Tx antennas). For one or more Tx antenna ports (e.g., each Tx antenna port) the WTRU may determine (e.g., based on channel measurements) to average λᵣ samples of the CSI array corresponding to adjacent Rx antennas. For one or more Rx antennas (e.g., each Rx antenna) the WTRU may determine to average λₜ samples of the CSI array corresponding to adjacent Tx antennas/antenna ports. In examples, the WTRU may determine to average (λᵣ×λₜ) sized blocks.

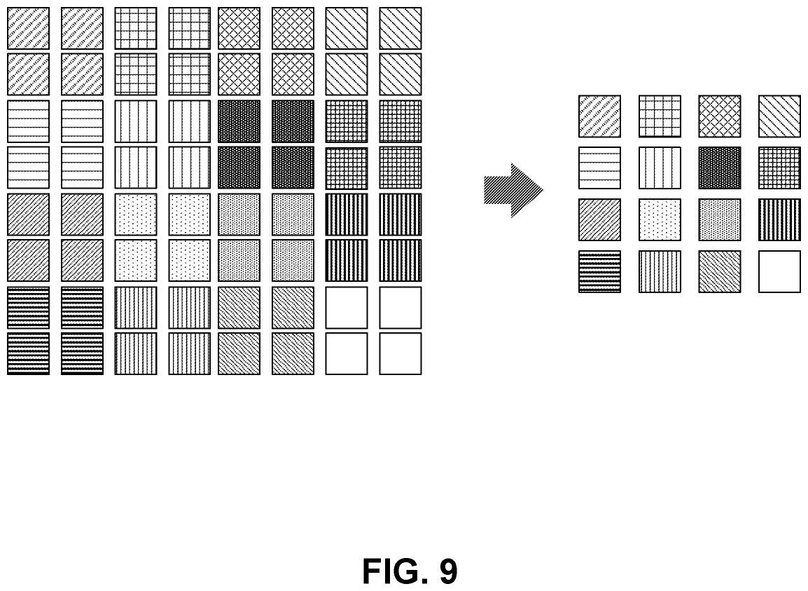

FIG. 9 shows an example of averaging in spatial-domain for pre-processing of an 8-by-8 matrix. In the example shown in FIG. 9, λᵣ=2 and λₜ=2.

The down conversion may be based on blocks correlation, for example, where the spatial-domain pre-processing for each (Nᵣ×Nₜ) CSI may be down-sampled to

$$\frac{{N}_{r}}{{λ}_{r}} \times \frac{{N}_{t}}{{λ}_{t}}$$

given a spatial correlation threshold (e.g., a specific spatial correlation threshold) (e.g., as described herein.

An average coefficient may be defined for the b-th block and may be denoted as h_{b}, where the coefficients (e.g., all the coefficients) may be averaged into a single value as:

$${h}_{b} = {\sum }_{i}^{{λ}_{r}} {\sum }_{j}^{{λ}_{t}} {h}_{( b - 1 ) {λ}_{r} + i , ( b - 1 ) {λ}_{t} + j}$$

where b=1, . . . , N_{B} may represent the block index. In examples, h_{b} may be the first block with respect to FIG. 9 (marked in white), which averages the CSI coefficients (e.g., all the CSI coefficients) associated with the neighboring REs marked in white.

An equivalent averaged matrix H′ may be constructed based on the averaged values. The vectorized form of the equivalent averaged matrix may be expressed as:

h=[h₁ . . . h_{N}_{_{B}}],

where h may be a (1×N_{B}) vector.

The correlation matrix, R, may define the correlation between different blocks as:

$$R = \frac{{h}^{H} h}{{‖ h ‖}^{2}}$$

where R may be an (N_{B}×N_{B}) matrix. The off-diagonal values of R may indicate the cross-correlation between the blocks.

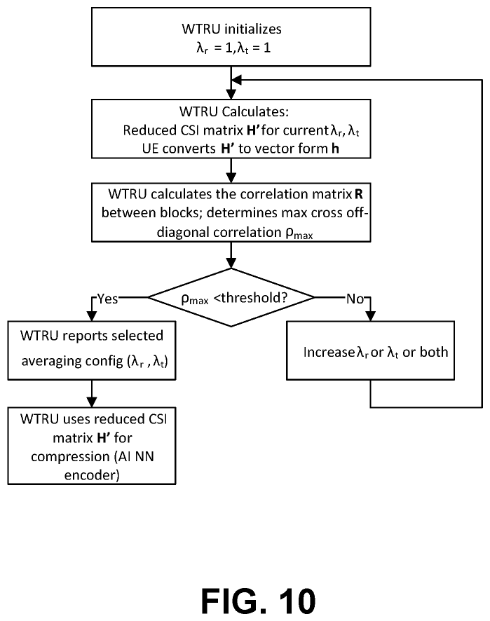

FIG. 10 shows an example of spatial-domain pre-processing. To attain a correlation threshold (e.g., a specific correlation threshold), the WTRU may start with a minimum block size of λᵣ=1 and λₜ=1 (e.g., no blocks/no averaging) and increment the block size iteratively by m across one or both dimensions. The maximum cross-correlation value ρₘₐₓ (e.g., off-diagonal values in R) may be calculated (e.g., at each iteration). The number of elements grouped in a block (e.g., each block) (λᵣ×λₜ) may be selected when ρₘₐₓ decreases below the configured spatial correlation threshold.

Example feature(s) associated with time domain pre-processing are provided. Where the AI NN encoder is an RNN, the age of a channel and/or age of samples (e.g., content) may be used to reduce input dimensionality (e.g., since the input may be a time series data). Reducing input dimensionality using the age of the channel and/or the age of content may be implemented through down-sampling or averaging (e.g., in different ways). The down-sampling/averaging may be dynamically adapted between one time instance and another time instance where a given time instance may correspond to one or more of the following units: time slots, symbol duration, SFN, or seconds/milliseconds. The dynamic adaptation may occur via the definition of one or more windows, whereby a window (e.g., each window) may be linked to either one or more down-sampling rate(s) or one or more fixed number of samples over which the averaging process may compute an average of the channel estimate. The window size, down-sampling rate(s), and/or number of samples to average over may be determined by static information (e.g., AI NN encoder type and/or WTRU antenna configuration) and/or dynamic information (e.g., SNR and/or application(s) being served). The dynamic adaption may occur via a timer/counter associated with a down-sampling rate and/or number of samples to average over. A timer/counter may include any process suitable for assessing a temporal duration. For example, a timer/counter may assess a number of system frames. For example, a time/counter may assess a number of time units (e.g., such as millisecond(s). The start of the timer/counter may trigger the WTRU to apply the down-sampling rate (e.g., ½, ¼, etc.) associated with the timer/counter. The length of the timer/counter, down-sampling rate(s), and/or number of samples to average over may be determined by static information (e.g., data processing model type (AI NN encoder model type) and/or WTRU antenna configuration) and/or dynamic information (e.g., SNR, application(s) being served). Dynamic adaption may occur via CSI feedback of the channel frequency response, which may shape the data to be input into the AI NN encoder as the real and imaginary parts (e.g., thereby leaving further implicit feature extraction to the AI NN encoder). In examples, explicit extraction of one or more features in the channel data (e.g., amplitude, phase, and/or SNR) before being input into the encoder may help in reducing input dimensionality. In examples, reshaping of the input as a function of the antenna configuration and selected model type (e.g., 2D or 3D configuration) may reduce computation complexity of the AI NN encoder.

Example techniques to leverage multiple WTRUs/users in proximity to reduce input dimensionality are provided. Correlation among channel matrices between nearby users/channels/sub-channels may be exploited to determine the down-sampling rate or number of samples to average over. For example, CSI values for users/channels/sub-channels in proximity may be correlated due to similar propagation paths, gains, delays and/or Angle(s) of Departure (AoD(s)). With assistance from a gNB, encoding at the WTRU may leverage the correlation between different users/channels/subchannels in proximity to reduce input dimensionality to the respective AI NN encoders. CSI from multiple users/channels/subchannels may be encoded in a distributed way with joint decoding/reconstruction at the gNB. For example, the gNB may have knowledge of multiple users located in proximity (e.g., to one another) and use the information to send an indication to the WTRU of the down-sampling rate to use or the number of samples over which to average the channel estimates. In the case where a WTRU may be in proximity to one or more other WTRUs (e.g., all of which are reporting channel estimates to the gNB), the WTRU may receive an indication from the gNB (e.g., via RRC signalling and/or messages, MAC CE, or DCI) to adjust (e.g., increase) the number of samples over which to average the CSI estimates or to select a different sampling rate (e.g., lower sampling rate). Even if the compression is carried out separately at Al NN encoders at respective WTRUs, the WTRUs/AI NN encoders (e.g., each WTRU/AI NN encoder) may benefit from the correlation among the CSI matrices to achieve a better trade-off between input dimensionality reduction and reconstructed CSI matching actual CSI. The dimensionality of the data at the AI NN encoder input may be reduced when the gNB uses information (e.g., on WTRUs located in proximity) to limit the angular range of directions that WTRUs (e.g., individual WTRUs) may need to scan for CSI estimates. For example, the gNB may indicate (e.g., explicitly indicate), to WTRU(s), an angular range of directions (e.g., 0°-45° with respect to a reference point) and/or granularity to scan (e.g., every 1°, 3°, 4°, etc.) via indications (e.g., RRC signaling and/or messages, MAC CE, or DCI) sent to respective WTRU(s). For example, the gNB may send (e.g., to WTRU(s)) information about the presence of other WTRU(s) in proximity. The WTRU may perform discovery and determine the angular range of directions to scan for CSI estimates and send back to the gNB. For example, WTRU(s) may do discovery of other WTRU(s) in proximity via sidelink. WTRU(s) may determine (e.g., jointly determine) the angular range of directions that a respective WTRU (e.g., each respective WTRU) may need to scan and send to the gNB for CSI estimates.

Multi-dimensional techniques are provided herein. Correlation among channel matrices/coefficients over space, time, and frequency may be used for down-sampling the acquired CSI values (e.g., prior to feeding the channel matrices/coefficients into the CSI compressor).

The spatial-domain pre-processing may include (e.g., may be expanded to include) pre-processing over the frequency and time domains.

The WTRU may determine to use the spatial-domain, frequency-domain, and/or time-domain pre-processing of the CSI. The WTRU may be configured (e.g., by the gNB) with a combination or order of dimensions (e.g., in the frequency, time, and/or spatial domain(s)) on which the WTRU may perform pre-processing. The order of dimensions may be defined as the order by which the dimensions (e.g., each of the more than one dimensions) is pre-processed by the WTRU. The WTRU may receive an indication (e.g., dynamic indication) from the gNB to perform pre-processing on a combination or order of dimensions. The configuration and/or indication may be received from the gNB via RRC (re) configuration signalling, DCI, or MAC CE. The WTRU may be configured with one or more rules and/or triggers to determine (e.g., autonomously determine) the combination or order of dimensions on which the WTRU may perform pre-processing.

The WTRU may determine a number of adjacent CSI samples that may be averaged (e.g., in no specific order) in the spatial domain, frequency domain, and time domain (e.g., in each CSI block of matrices spanning over space-time- and frequency). The adjacent CSI samples may be averaged in the spatial domain, then the frequency domain, and then the time domain.

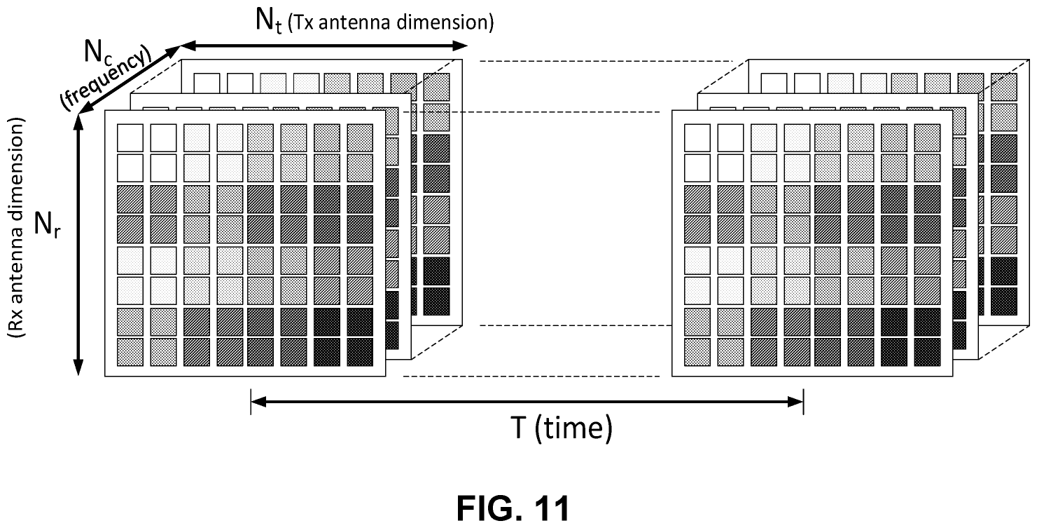

FIG. 11 shows an example of a CSI block over space, time, and frequency.

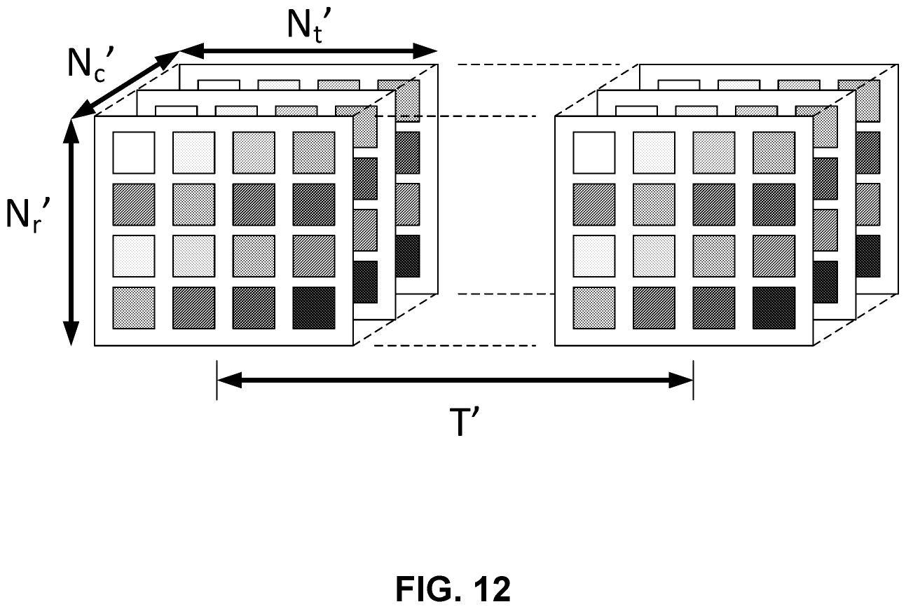

FIG. 12 shows an example of a reduced-size CSI block over space, time, and frequency.

The WTRU may acquire the channel estimates over N_{c} frequency-domain samples and T time-domain samples for (Nᵣ×Nₜ) elements, e.g., as described herein with respect to FIG. 11. The WTRU may reduce the size of the acquired CSI into N′≤N_{c} frequency-domain samples and T′≤T time-domain samples and (Nᵣ′Nₜ′)≤(Nᵣ×Nₜ) elements, as described herein with respect to FIG. 12.

The WTRU may partition the channel estimates in each (Nᵣ×Nₜ) matrix at the n_{c}-th frequency-domain sample and t-th time-domain sample into (λᵣₓ×λₜₓ)-sized blocks and average the coefficients of each block into a single value (e.g., the same technique may be repeated for some or all (Nᵣ×Nₜ) matrices in some or all selected frequency and/or time samples). The CSI size at a subcarrier or time slot (e.g., each subcarrier or time slot) may be down-sampled to

$$( \frac{{N}_{r}}{{λ}_{rx}} \times \frac{{N}_{t}}{{λ}_{tt}} ) .$$

The WTRU may partition the N_{c}-sized channel vector at the (nᵣ×nₜ)-th element in the t-th time sample into λ_{f}-sized sub-blocks and average the coefficients of each block into a single value (e.g., the same technique may be repeated for some or all channel vectors corresponding to the (Nᵣ×Nₜ) elements in some or all time samples). The number of frequency-domain samples may be reduced to

$${N}_{c}^{′} = \frac{{N}_{c}}{{λ}_{f}} .$$

The WTRU may partition the T-sized channel vector comprising of all (nᵣ×nₜ)-th channel coefficients in the n_{c}-th subcarrier in all T channel blocks into λₜ-sized sub-blocks and average the coefficients of each block into a single value. The number of CSI matrices in time domain may be reduced from T to

$${Y}^{′} = \frac{T}{{λ}_{t}} .$$

As described herein, the pre-processing technique may be expanded for each dimension, for example, for the spatial domain, frequency domain, and time domain.

For the spatial dimension, the down-conversion may be based on blocks correlation in the spatial domain, for example, where the spatial-domain pre-processing for each (Nᵣ×Nₜ) CSI may down-sample the CSI to

$$\frac{{N}_{r}}{{λ}_{rx}} \times \frac{{N}_{t}}{{λ}_{tx}}$$

given a spatial correlation threshold. An example implementation may include one or more of the following features.

The elements of the (Nᵣ×Nₜ)-sized matrix at the (n_{c}, t) frequency-time sample may be denoted by hₙ_{_{c}}_{,t,n}_{ᵣ}_{,n}_{ₜ}, where n_{c}, t, nᵣ, nₜ represent the indices for frequency, time, Rx antenna, and Tx antenna domains, respectively.

The average coefficient at the (n_{c}, t)-th frequency-time sample may be defined for the (λᵣₓ×λₜₓ)-sized b-th spatial-domain block denoted as h_{b}, where all the coefficients in the n_{c}-th subcarrier and t-th time slot are averaged into a single value as:

$${h}_{b} = {\sum }_{i}^{{λ}_{rx}} {\sum }_{j}^{{λ}_{tx}} {h}_{{n}_{c} , t , ( b - 1 ) {λ}_{rx} + i , ( b - 1 ) {λ}_{tx} + j}$$

where b=1, . . . , N_{B} is the block index.

The WTRU may use the per-block averaged coefficients to build the vectorized channel h and/or the correlation matrix R of the averaged channel matrix, as described herein.

To reach a configured spatial-domain correlation threshold, the WTRU may start with a minimum block size of λᵣₓ=1 and λₜₓ=1 (e.g., no blocks and no averaging) and increment the block size iteratively by m across one or both dimensions (e.g., λᵣₓ and λₜₓ define the length and width of the b-th block, respectively). At each y-th iteration, the maximum cross correlation value ρ_{s,max} (e.g., off-diagonal values in R) may be calculated. The number of elements grouped in each block (λᵣₓ×λₜₓ) may be selected as the maximum, last, and/or current value when the obtained cross-correlation ρ_{s,max} decreases below the configured spatial correlation threshold.

The same technique may be repeated for all (Nᵣ×Nₜ)-sized channel matrices at all selected n_{c}′ frequency and t′ time samples.

The block size for each (Nᵣ×Nₜ)-sized channel matrix at the (n′_{c}, t′) frequency-time sample may be denoted by λᵣₓ^{(n′}^{_{c}}^{,t′)}×λₜₓ^{(n′}^{_{c}}^{,t′)}). For a uniform down-sampling of all matrices across all subcarriers and time slots, the universal size block may be determined as:

$$( {λ}_{rx} , {λ}_{tx} ) \approx min ( {λ}_{rx}^{( {n}_{c}^{′} , {t}^{′} )} , {λ}_{tx}^{( {n}_{c}^{′} , {t}^{′} )} \vert ∀ {n}_{c}^{′} , {t}^{′} )$$

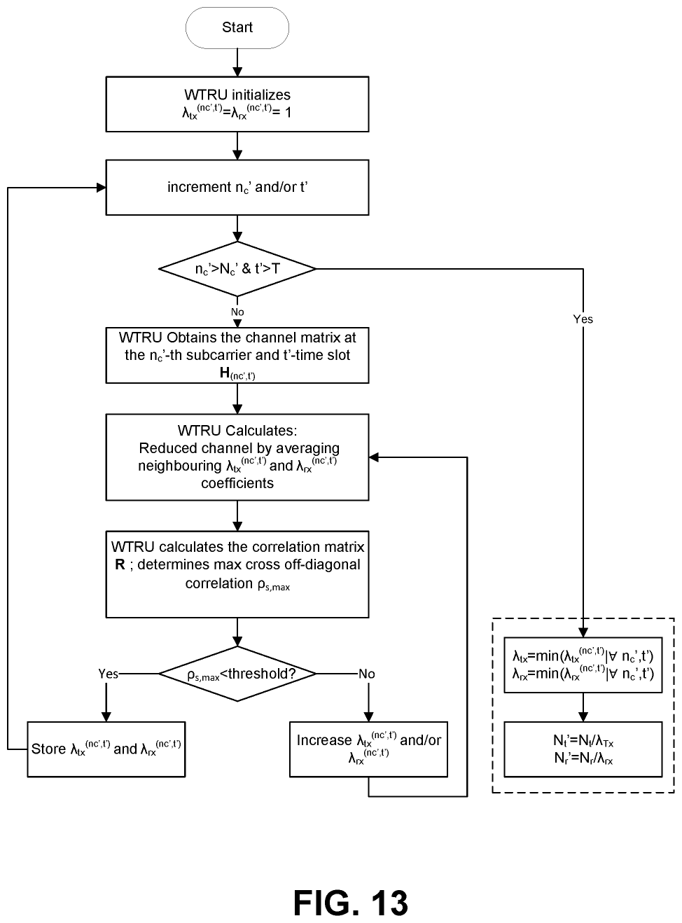

This technique is described with respect to FIG. 13.

FIG. 13 shows an example of spatial-domain pre-processing.

For the frequency dimension, the down-conversion may be based on the correlation between neighboring samples in the frequency-domain, where N_{c} channel coefficients may be down-sampled to

$$\frac{{N}_{c}}{{λ}_{f}} ,$$

given a frequency correlation threshold. An example implementation may include one or more of the features described in the following.

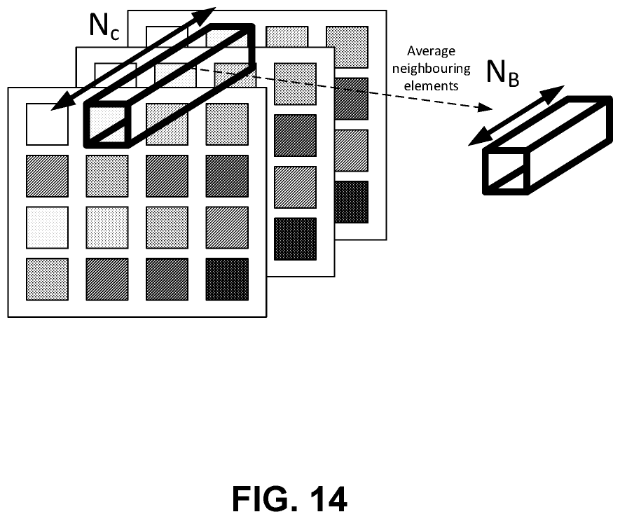

FIG. 14 shows an example of a channel vector at the (nᵣ, nₜ)-th element at the t-th time slot and the reduced-size vector.

The average coefficient at time t and (nᵣ, nₜ) antenna indices may be determined by averaging neighboring λ_{f} frequency-domain coefficients (e.g., as shown in FIG. 14). In each sub-carrier block, the λ_{f} elements (e.g., all λᵣ elements) may be averaged into a single value h_{b} as:

$${h}_{b} = {\sum }_{i}^{{λ}_{f}} {h}_{( b - 1 ) {λ}_{f} + i , t , {n}_{r} , {n}_{t}}$$

with b=1, . . . , N_{B} being the block index.

The WTRU may use the per-block averaged coefficients to build the vectorized channel h and/or the correlation matrix R of the averaged channel matrix, as described herein.

To reach a configured frequency-domain correlation threshold, the WTRU may start with a minimum block size of λ_{f}=1 and increment the block size iteratively by m. At each y-th iteration, the maximum cross correlation value ρ_{f,max} (e.g., off-diagonal values in R) may be calculated. The number of elements grouped in each λ_{f}-sized sub-carrier block may be selected as the maximum, last, and/or current value when the obtained cross-correlation ρ_{f,max} decreases below the configured frequency correlation threshold.

The same technique may be repeated for all (Nᵣ′×Nₜ′)-elements in each channel matrix at all t′=1, . . . , T′ time slots (e.g., Nᵣ′, Nₜ′ and T′ may be used for generalization, since unity lambdas are used without spatial-domain and/or time-domain pre-processing).

The sub-carrier block size for each (nᵣ′, nₜ′)-th element and t′-th time slot may be denoted by λₙ_{_{c}}^{n′}^{ₜ}^{,n′}^{ᵣ}^{,t′)}. In case the WTRU uses (e.g., requires) a uniform down-sampling for all sub-carriers channel elements and time slots, the universal size block may be determined as:

$${λ}_{f} \approx min ( {λ}_{{n}_{c}}^{( {n}_{t}^{′} , {n}_{r}^{′} , {t}^{′} )} \vert ∀ {n}_{t}^{′} , {n}_{r}^{′} , {t}^{′} )$$

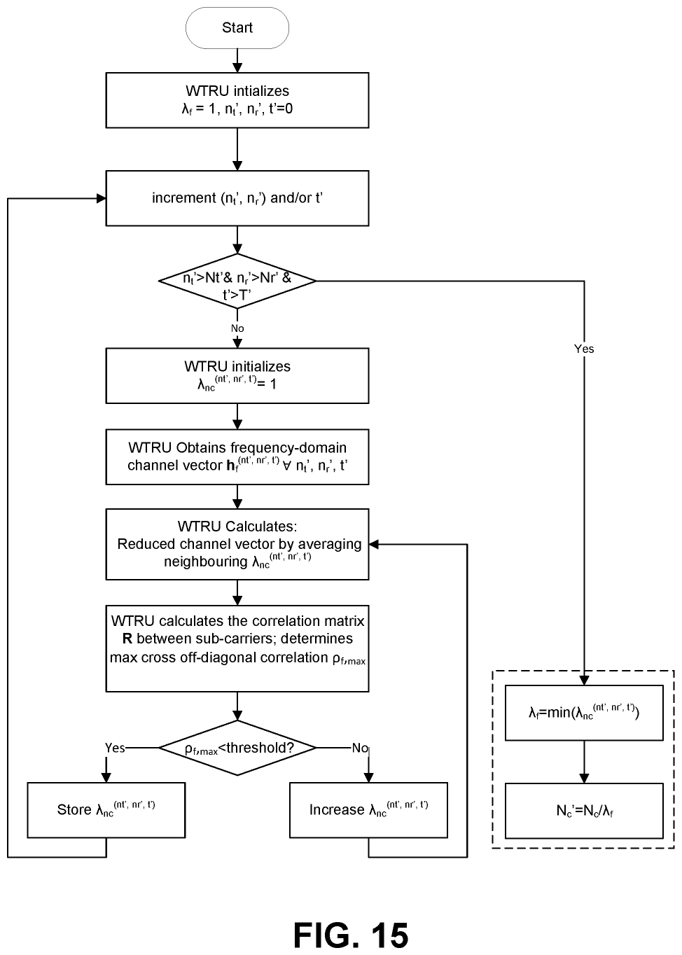

This technique is described with respect to FIG. 15.

FIG. 15 shows an example of frequency-domain pre-processing.

For the time dimension, the down-conversion may be based on the correlation between channel coefficients in neighboring time slots, where time-domain preprocessing may down-sample T channel blocks to

$$\frac{T}{{λ}_{t}} ,$$

given a time correlation threshold. An example implementation may include on or more of the following features.

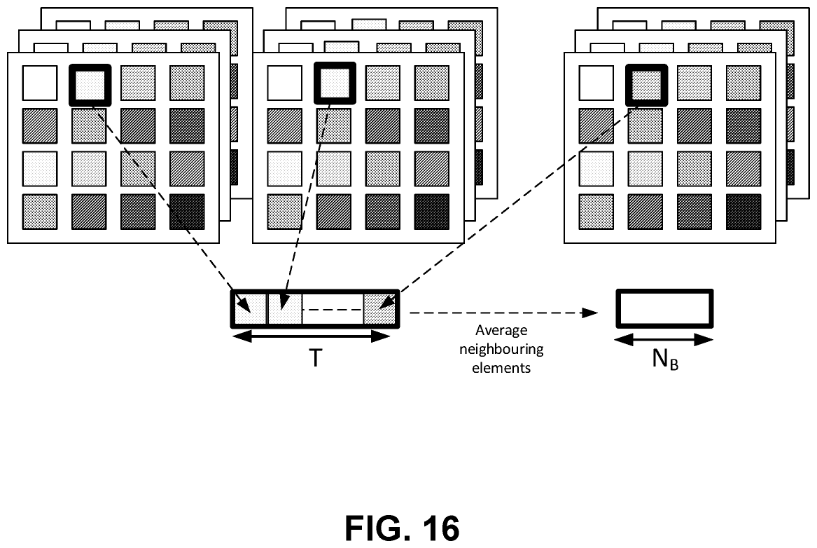

FIG. 16 shows an example of time-domain channel vector at the (nᵣ, nₜ)-th element at the no-th sub-carrier and the reduced size vector.

The average coefficient at the (nᵣ, nₜ)-th antenna index and the n_{c}-th frequency-domain index may be determined by time averaging neighboring λₜ time-domain coefficients (e.g., as shown in FIG. 16), as

$${h}_{b} = {\sum }_{i}^{{λ}_{t}} {h}_{{n}_{c} , ( b - 1 ) {λ}_{t} + i , {n}_{r} , {n}_{t}}$$

with b=1, . . . , N_{B} being the block index.

The WTRU may use the per-block averaged coefficients to build the vectorized channel h and/or the correlation matrix R of the averaged channel matrix, as described herein.

To reach a configured time-domain correlation threshold, the WTRU may start with a minimum block size of λₜ=1 and increment the block size iteratively by m. At each y-th iteration, the maximum cross correlation value ρ_{t,max} (e.g., off-diagonal values in R) may be calculated. The number of elements grouped in each λₜ-sized sub-carrier block may be selected as the maximum, last, and/or current value when the obtained cross-correlation ρ_{t,max} decreases below the configured time correlation threshold.

The same technique may be repeated for all (Nᵣ′×Nₜ′)-elements in each channel matrix in all n′_{c}=1, . . . , N_{c}′ sub-carriers (e.g., Nᵣ′, Nₜ′ and N_{c}′ may be used for generalization, since unity lambdas are used without spatial-domain and/or frequency-domain pre-processing).

The time-domain block size for each (nᵣ′, nₜ′)-th element and n′-th time slot may be denoted by λₜ^{n′}^{ₜ}^{,n′}^{ᵣ}^{,n′}^{_{c}}⁾. In case the WTRU uses (e.g., requires) a uniform down-sampling for all sub-carriers channel elements and time slots, the universal size block may be determined as

$${λ}_{t} \approx min ( {λ}_{t}^{( {n}_{t}^{′} , {n}_{r}^{′} , {n}_{c}^{′} )} \vert ∀ {n}_{t}^{′} , {n}_{r}^{′} , {n}_{c}^{′} )$$

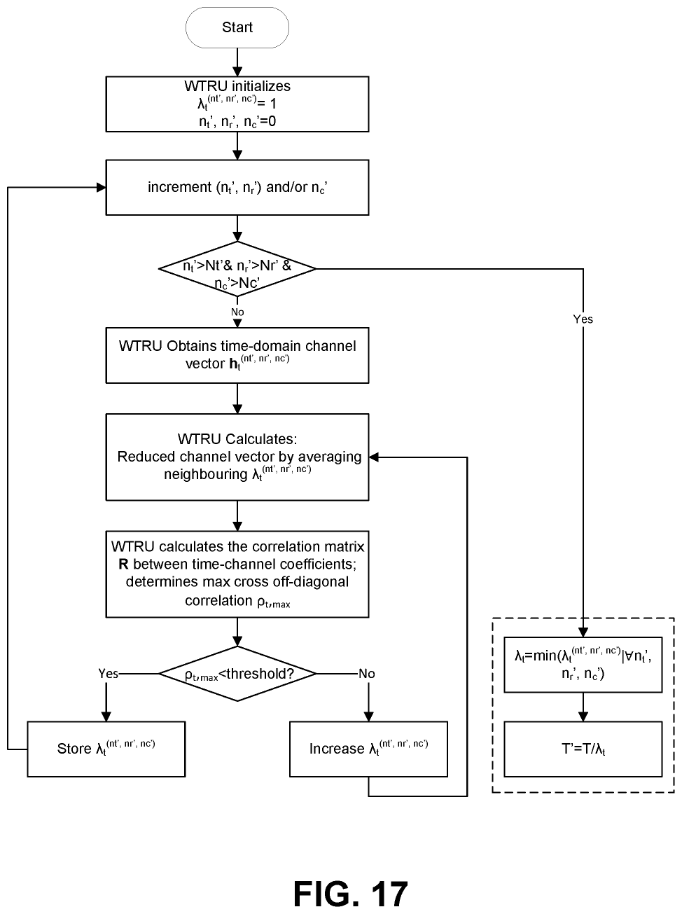

This technique is described with respect to FIG. 17.

FIG. 17 shows an example of time-domain pre-processing.

Combining multiple dimensions may be used herein. Multiple pre-processing techniques may be grouped together to achieve enhanced size reduction over multiple dimensions.

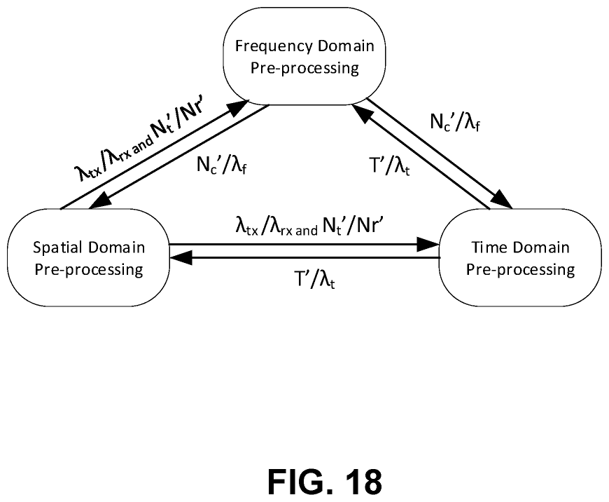

A WTRU may apply pre-processing on x dimensions and in an order, for example, where x={1,2,3}. The WTRU may determine the pre-processing order, or the pre-processing order may be indicated to the WTRU. In examples, the pre-processing techniques (e.g., three pre-processing techniques) may be applied in order (e.g., pre-processing technique 1, then pre-processing technique 2, and then pre-processing technique 3), where the inputs to one technique may be the outputs of another technique as described with respect to FIG. 18.

FIG. 18 shows an example of inputs and outputs associated with (e.g., into and from) each pre-processing technique.

A WTRU may determine the dimensions on which to perform pre-processing and/or the order of the pre-processing. The WTRU may be determine the dimensions and/or order based on (e.g., via) a configuration and/or an indication from the gNB. The WTRU may be configured with one or more triggers and/or one or more rules to determine (e.g., autonomously determine) the pre-processing dimensions and/or order. The trigger(s) may include at least one of the following: correlation between adjacent resources being above or below a possibly configurable threshold; coherence time, coherence bandwidth, and/or spatial correlation; time and/or measurement resource or feedback resource (e.g., every n-th feedback report may assume a first set of pre-processing dimensions and/or a first pre-processing order, and other feedback reports may assume a second set of pre-processing dimensions and/or a second pre-processing order, where some feedback reports may provide more complete CSI information without pre-processing and other feedback reports may provide incremental updates and may use more pre-processing); feedback resource; reference signal used to obtain the measurement (e.g., RS type and/or parameters of the RS); feedback report payload size; achievable CSI compression rate; layer 3 (L3) measurement (e.g., SINR, RSRP, or reference signal received quality (RSRQ)); channel matrix parameter (e.g., rank); priority (e.g., a priority of the feedback report and/or priority of the associated transmissions; and/or cell, TRP, and/or panel ID.

A WTRU may report (e.g., to the gNB) the set of x dimensions and/or the order on which the WTRU performs pre-processing. The WTRU may provide the report at the same time as reporting the associated CSI feedback. The WTRU may provide the report periodically. For cases where a CSI feedback does not include a report of pre-processing dimensions and/or order, the associated pre-processing dimensions and/or order may reuse the values included in previously reported pre-processing dimensions and/or order.

A WTRU may report the value(s) of the trigger(s) and/or measurement(s) that the WTRU obtained to determine the pre-processing dimensions and/or order. If the pre-processing dimensions and/or order are determined based on coherence time and/or bandwidth, the WTRU may report the values obtained for coherence time and/or bandwidth.

A WTRU may perform non-uniform down-sampling in one or more dimensions. In examples, the WTRU may segment the CSI into regions, where the regions (e.g., each region) may have different pre-processing granularity and the pre-processing may be done for different dimensions and in a different order. A region may include a subset of the overall subbands, slots, and/or antenna pairs. In examples, in frequency the WTRU may segment a BW or BWP into subbands. The WTRU may perform down-sampling of different granularity in the subbands (e.g., each subband). The WTRU may be configured and/or indicated with the regions. In examples, the WTRU may determine and/or report the regions (e.g., number of regions, locations of regions and pre-processing granularity, dimensions, and/or order of the region).

Techniques for an AI NN encoder to support multiple input sizes are provided. A single data processing model (e.g., AI NN encoder model) may be used to process channel input to fit the model.

The WTRU may be configured with an AI NN encoder model with a predetermined number of parameters, e.g., input dimensions, number of layers, etc. The AI NN encoder may have an input dimension of (Kₑ×Nₑ×Mₑ), where Kₑ, Nₑ, and Mₑ may be the number of subcarriers/RBs/subbands, the number of receive antennas, and the number of transmit antennas, respectively. The link configuration may change (e.g., dynamically or semi-statically) and the CSI corresponding to the link parameters may not match the AI NN encoder size. For example, the WTRU may be configured with a BWP (e.g., corresponding to K̅ CSI samples in the frequency domain) where K̅ may be greater or smaller than Kₑ. The number of configured Tx antenna ports M for the transmission to the WTRU may be greater or smaller than Mₑ. If the input dimension is greater than the configured Al model input dimension, the WTRU may use the same model multiple times by splitting the input dimension to fit the configured Al model input dimension and feedback the compressed outputs. The WTRU may extract the features to fit the Al model's dimension by dimensionality-reduction techniques, such as PCA or ICA.

An example AI NN encoder model to support multiple input sizes is provided. The WTRU may be configured with multiple Al models (e.g., each dealing with a set of input sizes). Each set of models may be capable of handling a different set of input sizes, for example, covering a number (e.g., a large number) of input combinations with a minimum number of models. As shown with respect to FIG. 5, an AE may comprise two parts that are jointly trained: the AI NN encoder that compresses a high-dimensional input h using E (h; Θₑ) to obtain a low-dimensional latent representation z where Θₑ represents the encoder weights, and the AI NN decoder that performs dimensionality expansion of the input z using D (z, Θ_{d}) to recover h, where Θ_{d} represents the decoder weights. Given N training sample {h₁, . . . , h_{N}}, the optimization problem may be represented by the following equation:

$$( {Θ}_{e}^{★} , {Θ}_{d}^{★} ) = arg {min}_{{Θ}_{e} , {Θ}_{d}} {\sum }_{i = 1}^{N} {‖ {h}_{i} - D ( E ( {h}_{i} ; {Θ}_{e} ) ; {Θ}_{d} ) ‖}_{2}^{2}$$

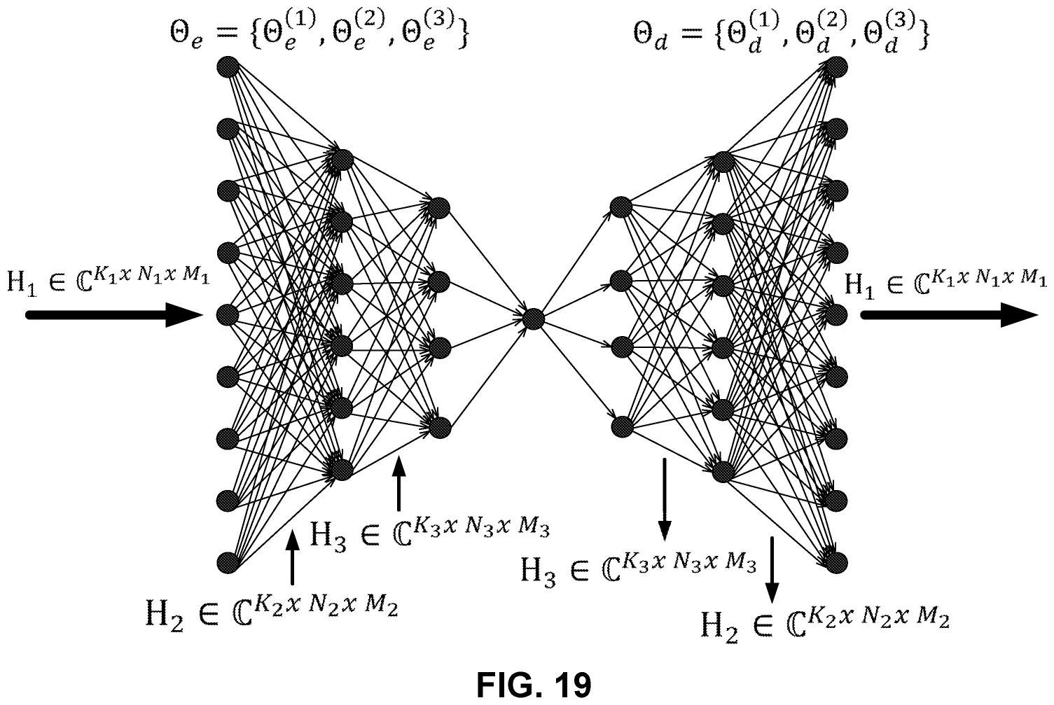

The above loss function may be configured such that (e.g., may require that) the input size, the output size, and the compression ratio are fixed. The WTRU may (e.g., be required to) support multiple Al NN models to handle different input CSI sizes. To handle different input sizes with acceptable complexity and memory requirements, a model (e.g., a single model) may be used, but may be (e.g., may need to be) jointly trained on accepting different input data from one or more of the encoder layers (e.g., any of the encoder layers) and reconstructing the associated outputs from the respective decoder layers. For example, FIG. 19 shows an example of multi-input-multi-output AE. As shown in FIG. 19, an architecture for a multi-input-multi-output AE that may be trained with multiple samples from {H₁, H₂, H₃}, where H₁, H₂, H₃ represent CSI 3-D arrays of different sizes, e.g., to support different bandwidths or delay spreads, different numbers of Rx antennas, and Tx antenna ports. The loss function for the multiple-input-multiple-output AE may be designed to minimize the following:

$$( {Θ}_{e}^{★} , {Θ}_{d}^{★} ) = arg {min}_{{Θ}_{e} , {Θ}_{d}} {\sum }_{i = 1}^{3} {Loss}_{i}$$

where Lossᵢ=f(Hᵢ; Θₑ^{(j)}, Θ_{d}^{(j)}), for i, j=1,2,3, and j≥i. The exemplary architecture in FIG. 19 together with the exemplary loss function may lead to having a single model that may compress and decompress multiple input sizes. If the WTRU is configured with multiple models (P) with each handling multiple input sizes (L), the WTRU may have P x L possible input dimensions to use. The WTRU may choose between the different data processing models (e.g., AI NN encoder models) and the selected input layer of the chosen model based on the input dimension. In case of any mismatch between the input dimension and any of the configured input dimensions, the WTRU may choose the model and the layer index with the closest dimension to the input dimension. Zero padding or feature extraction techniques may be applied to account for the mismatch (e.g., minimal mismatch). In examples, the WTRU may split the input size to two or more sub-arrays and feed the different sub-arrays to the multiple layers of the different AI NN encoder models. For example, given an input (e.g., CSI or interference) of dimension (K×N×M), the WTRU may split the input in two sub-arrays, e.g., K₁×N×M, K₂×N×M), with K=K₁+K₂, such that the sub-arrays (e.g., both sub-arrays) may fit into the inputs of the preconfigured input dimensions (e.g., any of the preconfigured input dimensions). The output of the different model layers may be combined and sent as a one latent vector to the gNB. The WTRU may report the selected model(s) and the corresponding input layers indices to the gNB for decoder matching and decompression. For example, with P=4 models and L=8 layers/model, the WTRU may indicate one or more of a possible 32 options to the gNB. In examples, based on the bandwidth allocated to the WTRU, the gNB may inform the WTRU of the model(s) and/or layer(s) to use for compression.

Feature(s) associated with determining the pre-processing type are provided. WTRU autonomous pre-processing type selection may be used. A WTRU may be configured with a set of reference data processing models (e.g., AI NN encoder models). The WTRU (e.g., one or more data processing models of the WTRU) may support multiple pre-processing types. The WTRU may select one or more pre-processing type(s) based on whether a data processing model at the WTRU supports the pre-processing type(s). The WTRU may receive one or more reference signal(s) (e.g., one or more configured reference signals). The WTRU may perform CSI measurements (e.g., channel response matrix CFR, CQI, PMI, RI, and/or interference measurements), for example using the configured reference signals (e.g., perform measurements on reference signal(s) to determine CSI). The WTRU may perform channel measurements (e.g., channel coherence BW, channel coherence time, delay spread, Doppler spread and/or the like) to determine which pre-processing type may be applicable for the channel conditions (e.g., the WTRU may select a pre-processing type based on the channel conditions). The WTRU may calculate the CSI size after a first pre-processing type is performed, for example, if the WTRU determines that the first pre-processing type is applicable to the current channel conditions and the WTRU is configured with a data processing model (e.g., an AI NN encoder model) supporting the first pre-processing type (e.g., the WTRU may select the pre-processing type based on the data processing model). The WTRU may determine that frequency domain pre-processing is applicable if the coherence BW of the channel exceeds a threshold (e.g., a configured threshold). The WTRU may determine that frequency domain pre-processing is not applicable if the coherence BW of the channel is below the threshold. In examples, the WTRU may determine that frequency-domain pre-processing is supported by a data processing model of the WTRU. The WTRU may calculate the CSI size after a second pre-processing type, for example, if the WTRU determines that the second pre-processing type is applicable to the current channel conditions and the WTRU is configured with a data processing model (e.g., an AI NN encoder model) supporting the second pre-processing type (e.g., the WTRU may select the pre-processing type based on the data processing model). The WTRU may calculate the CSI size after angle-delay domain pre-processing, for example, if the WTRU is configured with a data processing model (e.g., an AI NN encoder model) trained on angle-delay domain data. The WTRU may select the pre-processing type that results in the smaller CSI size. For example, the WTRU may (e.g., as part of the pre-processing type selection process) determine that pre-processing the CSI using a first pre-processing type generates pre-processed CSI of a first size and that pre-processing the CSI using a second pre-processing type generates pre-processed CSI of a second size. The WTRU may select the first pre-processing type if the first size is smaller than the second size. The WTRU may select the second pre-processing type if the second size is smaller than the first size. The WTRU may pre-process the measured CSI (e.g., associated with the current channel) using (e.g., based on) the selected pre-processing type. The WTRU may generate compressed CSI by compressing the pre-processed CSI using the configured data processing model (e.g., AI NN encoder model) compatible with (e.g., that supports) the selected pre-processing type. The WTRU may send an indication of (e.g., report) the selected pre-processing type and/or the selected pre-processing parameters to the gNB (e.g., to a network). The WTRU may send (e.g., report) the compressed CSI to the gNB (e.g., to the network).

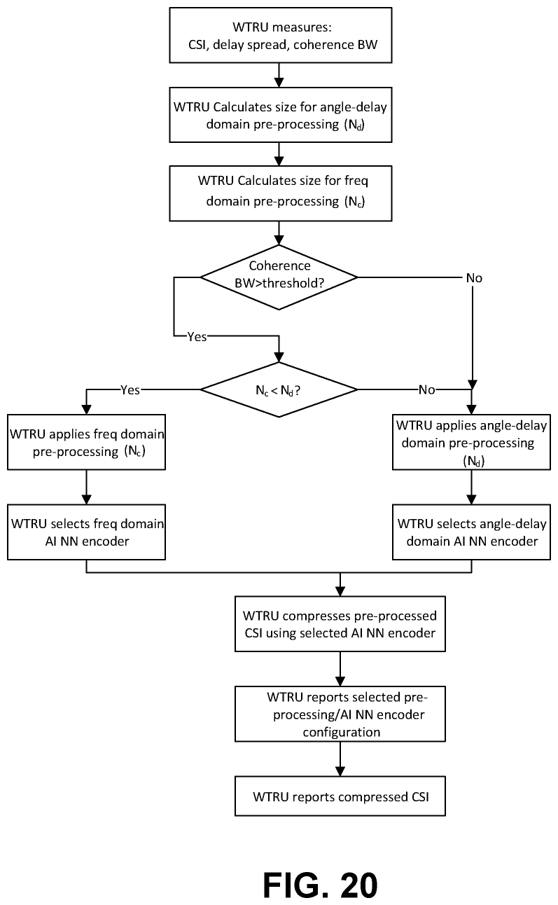

In examples, the WTRU may be configured with two data processing models (e.g., AI NN encoder models): a first encoder trained in frequency domain and a second encoder trained in the angle-delay domain. The WTRU may select (e.g., autonomously select) the pre-processing type as a function of channel conditions (e.g., based on one or more determined channel condition(s) associated with pre-processing), as shown with respect to FIG. 20.

FIG. 20 shows an example of WTRU autonomous selection of pre-processing type.

As shown in FIG. 20, a WTRU with Nᵣ receive antennas and configured for Nₜ CSI-RS antenna ports may measure the channel response matrix. The WTRU may measure the channel delay spread T (e.g., or the RMS delay spread τ_{RMS}). The delay spread measured in samples may be N_{d} (e.g., a size for angle-delay domain pre-processing). For angle-delay domain pre-processing, the size of the pre-processed CSI may be N_{d}×Nᵣ×Nₜ. The WTRU may measure the coherence BW of the channel and may determine if frequency-domain pre-processing is applicable, for example, if the coherence BW of the channel exceeds a configured threshold (e.g., as illustrated in FIG. 20). The WTRU may calculate the number of frequency-domain samples after pre-processing (e.g., a size for frequency domain pre-processing), N_{c}. For frequency-domain pre-processing, the size of the pre-processed CSI may be N_{c}×Nᵣ×Nₜ.

The WTRU may determine to use the frequency domain pre-processing, for example, if N_{c}<N_{d} (e.g., if the size of pre-processed CSI generated using frequency domain pre-processing is smaller than the size of pre-processed CSI generated using angle-delay domain pre-processing). The WTRU may perform (e.g., apply) the frequency domain pre-processing. The WTRU may select a frequency domain Al NN encoder and apply the pre-processed CSI to the input of the AI NN encoder trained on frequency-domain data. If N_{c}≥N_{d} (e.g., if the size of pre-processed CSI generated using angle-delay domain pre-processing is smaller than the size of pre-processed CSI generated using frequency domain pre-processing), the WTRU may perform (e.g., apply) angle-delay domain pre-processing. The WTRU may select an angle-delay domain AI NN encoder and apply the pre-processed CSI to the input of the AI NN encoder trained on angle-delay domain data. The WTRU may compress the pre-processed CSI using the selected AI NN encoder. The WTRU may report (e.g., to the gNB) the selected pre-processing type, parameter configuration, and/or the selected AI NN encoder. The WTRU may report the compressed CSI data to the gNB.

A WTRU may select pre-processing (e.g., a pre-processing type) and an AI NN encoder (e.g., a combination of pre-processing and AI NN encoder). A WTRU may be configured with a set of reference Al NN encoders. The AI NN encoders may differ from each other in one or more of the following aspects: number of input values in one or more dimensions (e.g., number of transmit antennas, number of receive antennas, number of sub-bands/subcarrier spacings, etc.); number of output values (e.g., size of compressed output); and/or achieved compression ratio.

The WTRU may be configured with a set of pre-processing techniques. The pre-processing techniques may differ from each other in one or more of the following aspects: the pre-processing type (e.g., the domain in which pre-processing operation occurs such as antenna, frequency, etc.); the pre-processing process (e.g., averaging, conversion to another domain such as angular-delay domain, etc.); the number of input values for the pre-processing technique; and/or the number of output values for the pre-processing technique.

The WTRU may be configured (e.g., by the gNB) to send a CSI report. The CSI report configuration may indicate the requested report size. The report size may be included (e.g., explicitly included) in the configuration in terms of the number of allocated bits. In examples, the report size may be implicitly indicated by the choice of the resources (e.g., time-frequency resources) allocated for the CSI report.

The WTRU may determine (e.g., based on the different combinations of pre-processing techniques and AI NN compression models that are configured) that a combination (e.g., one combination) of pre-processing technique and AI NN compression model may satisfy the CSI report size indicated by the gNB in the CSI report configuration. The WTRU may utilize the identified combination of pre-processing technique and AI NN compression model to process the CSI (e.g., to compress the CSI).

In examples, the WTRU may determine (e.g., based on the different combinations of pre-processing and AI NN compression models that are configured) that more than one combination of pre-processing and AI NN compression model may satisfy the CSI report size indicated by the gNB in the CSI report configuration. The WTRU may indicate its choice of the combination of the pre-processing technique and AI NN compression model explicitly in the CSI report. The WTRU may indicate its choice of the pre-processing and AI NN compression model implicitly by choosing a resource for CSI report transmission from a set of multiple resources configured by the gNB. While the configured resources (e.g., each of the configured resources) may support the same CSI report size, each configured resource may indicate a different choice of pre-processing and AI NN compression model combination.

In examples, if the WTRU determines that more than one combination of pre-processing and Al NN compression model satisfies the CSI report size indicated by the gNB in the CSI report configuration, the WTRU may choose a combination of the pre-processing and AI NN compression model that maximizes the output resolution for the configured maximum size of the CSI report. The WTRU may choose the combination that results in the smallest compression ratio.

The CSI report configuration may include the minimum quality of the compressed output requested (e.g., required) by the gNB, for example, which may correspond to one of a compression quality metric, a compression ratio, etc.

The compression quality metric may be based on the difference (e.g., mean squared error) between the actual CSI report quantity (e.g., channel response) and the estimated CSI report quantity (e.g., after the compression and decompression using the indicated pre-processing/post-processing techniques or compression/decompression using the NN). The values of the compression quality metric for each compression technique and NN model may be specified (e.g., further specified) for different conditions (e.g., channel characteristics such as indoor or outdoor deployment, static or mobile scenario, etc.).

The WTRU may be configured with a set of values corresponding to the achieved compression quality of various pre-processing and AI NN compression models (e.g., individually). The WTRU may evaluate the compression quality (e.g., overall compression quality) of the CSI report (e.g., that includes contributions from the pre-processing and the AI NN compression model) to determine which pre-processing technique and AI NN compression model to use for CSI report processing. The WTRU may, for example, determine the overall compression quality by adding the individual compression qualities for the pre-processing and the AI NN compression model.

The individual pre-processing and AI NN compression model selected by the WTRU for CSI report processing may not have compatible input-output dimensions. In such a case, the WTRU may have a choice of techniques to align the dimensions of the signals at the inputs and outputs of individual processing blocks, such as truncation, sub-sampling, interpolation, zero filling, mirroring, etc. The technique(s) used by the WTRU to align the dimensions of the signals at input of different processing steps (e.g., align the dimensions of the signals at the input of the pre-processing block and signals between the output of the pre-processor and the input of the AI NN compression model) may be determined by the WTRU based on one or more of the following considerations: the configured compression quality requirement, WTRU capabilities, etc.

The WTRU may be configured with the dimension alignment technique. The configuration may be specified for different conditions (e.g., channel characteristics such as indoor or outdoor deployment, static or mobile scenario, etc.).

The WTRU may determine the appropriate technique for aligning the signals at the inputs of different processing steps and may include its choice in the CSI report.

Example feature(s) associated with indicating the pre-processing type (e.g., the selected pre-processing type) are provided. Determination of pre-processing type may be done by the WTRU or by the NW (e.g., a gNB in the NW, for example, with assistance information from the WTRU).

The WTRU may encode the delta (e.g., only the delta) in CSI feedback (e.g., the changes in the current CSI report with respect to the previous CSI report), for example, when the WTRU determines that the CSI feedback reports are correlated (e.g., highly correlated) across domains (e.g., all domains such as time, frequency, angle-delay, and/or spatial domains). By encoding the delta (e.g., only the delta), the WTRU may be able to provide a CSI feedback of smaller size with the same reconstruction quality. The decoder (e.g., at the gNB) may receive the delta as encoded CSI and use the weights in the AI NN decoder to decode the signal.

A WTRU may be configured with a set of reference data processing models (e.g., AI NN encoder models) and may support multiple pre-processing types. Techniques to indicate the pre-processing type may include the WTRU indicating the type of preferred AI NN encoder or the AI NN encoder the WTRU has selected. Selection of the data processing model (e.g., AI NN encoder model) to use may change depending on dynamic information. The dynamic information may include one or more of the following: the uplink payload budget (e.g., PUSCH payload size); channel condition(s) (e.g., change in coherence BW); the reconstruction quality (e.g., selected by either WTRU or gNB)). Selection of the data processing model (e.g., AI NN encoder model) may depend on more static information (e.g., WTRU antenna configuration).

Indicating the pre-processing type may involve indicating (e.g., to a NW) one or more of the following information: measured channel parameter(s) information (e.g., channel measurement parameter(s) and/or channel condition(s)); frequency domain pre-processing information; angle-delay domain pre-processing information; time domain pre-processing information; or spatial domain pre-processing information.

Measured channel parameter(s)/condition(s) may be included in the information. In examples, the WTRU may report channel parameters (e.g., additional channel parameters) measured, e.g., to enable the gNB to select the pre-processing type and/or the AI NN encoder. For example, the WTRU may report the measured channel delay spread T/RMS delay spread τ_{RMS}, the coherence time of the channel, and/or the channel coherence bandwidth B_{c}. If a WTRU (e.g., a data processing model of the WTRU) supports frequency-domain CSI pre-processing, the WTRU may decide to report the measured channel coherence bandwidth B_{c} (e.g., in units of RBs) to the gNB when B_{c}≥B, where B may be a pre-configured threshold set by the gNB or by the WTRU and approved by the gNB. In examples if multiple AI NN encoders trained on different domain CSI are available, the WTRU may select the AI NN encoder with frequency-domain pre-processing if B_{c}≥B, and report of the selected encoder to the gNB. If a data processing model (e.g., an AI NN encoder model) in the WTRU supports spatial-domain pre-processing, the WTRU may determine spatial correlation among antenna elements and report it to the gNB. The WTRU may be configured to report spatial correlation between antenna elements, for example, as the number of antenna elements for which the channel correlation exceeds a threshold, which may be pre-configured by the gNB and shared with the WTRU (e.g., via RRC signaling) or pre-configured by the WTRU and reported to the gNB. Exceeding the threshold may result in the WTRU selecting an AI NN encoder trained on spatial domain CSI. The WTRU may have multiple AI NN encoders trained on different domain CSI data and may indicate to the gNB the selected AI NN encoder. If a data processing model (e.g., an AI NN encoder model) in the WTRU supports angle-delay domain pre-processing, the WTRU may measure and/or report the delay spread of the channel and/or the RMS delay spread. The WTRU may use the full channel matrix and/or the delay spread to determine the number of first significant N_{d} rows of the channel matrix and may report (e.g., only report) the truncated channel matrix. The WTRU may select the angle-delay domain pre-processing, for example, if the AI NN encoder is trained on angle-delay domain CSI. The WTRU may select angle-delay pre-processing if the channel delay spread and/or RMS delay spread exceeds a pre-configured threshold or if the uplink payload budget (e.g., PUSCH payload size) only allows the WTRU to report the first significant N_{d} rows of the channel matrix. If a data processing model (e.g., an AI NN encoder model) in the WTRU supports time-domain pre-processing, the WTRU may compute the coherence time of the channel by comparing one or more channel correlation values measured at different times to the channel correlation threshold. The WTRU may report the channel coherence time periodically to the gNB or when prompted by the gNB. In examples, the WTRU may take advantage of the correlation of CSI instances over time and may save and use stored CSI estimates from previous time instances and encode and/or decode (e.g., and only encode and/decode) the change in the CSI estimate from the previous time instance and report the estimates and/or the change to the gNB. The age of the sample may determine the size of the window over which the WTRU may measure and/or report CSI estimates to the gNB. If the WTRU has multiple data processing models (e.g., AI NN encoders) trained on different domain CSI data, the WTRU may select the AI NN encoder with time domain pre-processing, for example, if the channel coherence time exceeds a coherence time threshold, which may be configured by the gNB and shared with the WTRU (e.g., via RRC signalling) during initial configuration or pre-configured by the WTRU and indicated to and/or approved by gNB.

Indicating the pre-processing type may involve indicating one or more of the following information to the NW. For frequency domain pre-processing, the WTRU may report the number of averaged frequency-domain CSI values to the NW (e.g., via RRC signalling and/or messages, MAC CE, or UCI) either explicitly (e.g., signalling of CSI-RS density) or implicitly (e.g., indication of odd/even RBs and/or indication of the number of antenna ports). The WTRU may report the CSI size after frequency-domain pre-processing. For frequency domain pre-processing, the WTRU may select to average CSI-RS over every n number of RBs, with the value of n depending on factors (e.g., channel conditions) that the WTRU may be monitoring, or that the gNB may be monitoring and signaling back to WTRU. In examples, for the frequency domain, the WTRU may perform measurements of the radio link interfaces (e.g., Uu link or Sidelink) associated with the WTRU and report the measurements to the gNB/NW to assist gNB/NW in determining the pre-processing type. The measurements may assist in determining the nature of CSI-RS transmissions (e.g., periodicity to configure in the time domain).

In the case where, for frequency domain pre-processing, the WTRU may select to average CSI-RS over every n number of RBs, with the value of n depending on factors (e.g., channel conditions) that the WTRU may be monitoring, or that the gNB may be monitoring and signaling back to the WTRU, one or more of the following may apply. In examples, factors/parameters related to channel conditions that may impact the value of n may include one or more of the following: channel coherence bandwidth; previous channel measurements; channel statistics (e.g., frequency correlation coefficients); etc. Changes in listed factors/parameters beyond a certain pre-configured threshold (e.g., by the gNB/NW) may trigger the WTRU to dynamically update n and report the change to the gNB. For example, in the case where there is a change in the coherence bandwidth (e.g., from x Hz to y Hz) in a period of time t<T (e.g., where the value(s) of T may be configured by the NW), the WTRU may select n of a different value and signal the updated n value to gNB. In the case where gNB may have detected a change in one or more factors/parameters, the gNB may signal the change to the WTRU. Trigger for gNB to signal change to the WTRU may be one or more factors/parameters related to channel conditions. Re-evaluation of the value of n may be triggered by gNB based on reception of multiple NACKs from the WTRU. The gNB may signal the detected change(s) in factors/parameters to the WTRU (e.g., sending an implicit indication to the WTRU to update the value of n). The gNB may decide to update the value n based on a change in one or more factors/parameters. The gNB may signal (e.g., explicitly signal) the new value of n to the WTRU.

In examples, for the time domain, the WTRU may perform measurements of the radio link interfaces (e.g., Uu link or Sidelink) associated with the WTRU and report the measurements to the gNB/NW to assist gNB/NW in determining the pre-processing type (e.g., periodicity to send reference signals for the WTRU to do channel estimation). In examples, changes in reporting frequency and/or periodicity/offset may be triggered by detection of errors in CSI compression. For example, in the case of the RNN, the AI NN encoder may be trained by setting the delayed version of the channel as the desired output, whereby the delay may be a function of the channel coherence time.

For time domain pre-processing, the WTRU may be configured with one or more windows. One or more of the windows (e.g., each window) may be linked to a number of samples or sampling rate over which the WTRU may compute an average of the channel estimate. For example, for each window, the gNB may send one or more reference signal(s) to the WTRU. The WTRU may use the reference signal(s) to compute the channel estimate. The WTRU may transmit the feedback to the gNB (e.g., back to the gNB). The window size may be determined by the gNB or by the WTRU. The window size may be indicated to the gNB (e.g., based on static or dynamic information). For example, static information may include AI NN encoder type and/or WTRU antenna configuration. Dynamic information may include SNR, application(s) being served, reconstruction quality of the channel estimate, uplink payload budget, and/or age of samples in the case of RNN. A timer or counter may be implemented. The timer or counter may be associated with a number of measurements for the channel estimate (e.g., start of the timer or counter may trigger the gNB to send one or more reference signal(s) to the WTRU at a pre-determined periodicity (e.g., measured in time units or number of samples) and the WTRU may use the reference signal(s) to estimate the channel and transmit the feedback back to the gNB). The start of the timer or counter may be determined by the WTRU and indicated to the gNB or vice-versa. The triggering of the timer or counter and the length of the timer or counter (e.g., measured in any time units or number of samples) may be determined based on static information (e.g., AI NN encoder type and/or WTRU antenna configuration) and/or dynamic information (e.g., SNR, application(s) being served, reconstruction quality of the channel estimate, uplink payload budget, and/or age of samples in the case of RNN). In examples, the encoder at the WTRU and/or decoder at the gNB may exploit correlations in CSI values over time for a sequence of channel estimates by reporting the change (e.g., only the change) in CSI estimates (e.g., referred to as the delta) to reduce CSI feedback overhead, e.g., while achieving the same reconstruction quality. The WTRU and/or gNB may save CSI values of previous instances and use them in the encoding and/or decoding process. The WTRU may transmit an indication to the gNB that the encoded signal corresponds to a change in CSI from the CSI in the previous time instance. Since the payload is smaller, the WTRU may be able to include additional information (e.g., explicit feature extractions such as amplitude and/or phase) in the CSI report. In examples, the WTRU may send (e.g., to the gNB) an indication that the encoded CSI is independent of previously encoded CSI sent in past time instances.

Indicating the pre-processing type may involve indicating one or more of the following information to the NW (e.g., to a gNB in the NW). The information may include spatial domain information. In examples, if the WTRU selects spatial-domain pre-processing, the WTRU may report the measured (e.g., or selected) averaging length in the Rx antenna dimension of the CSI array (rx), and/or the averaging length in the Tx antenna dimension of the CSI array (tx). The gNB may exploit spatial correlations in CSI values between WTRUs, antenna elements, channels, and/or sub-channels. The correlation may be determined by WTRU or gNB. For example, the gNB may determine correlation between two or more WTRU(s) and indicate a pre-processing type to each respective WTRU based on the correlation amount. For example, where there may be a high correlation (e.g., beyond a threshold configured by gNB, WTRU A, and/or WTRU B) between WTRU A and WTRU B, the gNB may lower the periodicity of sending reference signals to WTRU A and/or WTRU B, indicating a lower instance of both WTRUs computing channel estimates and transmitting the estimates back to the gNB. The gNB may use information on WTRUs located in proximity to limit the angular range of directions that each respective WTRU has to scan and compute CSI estimates. In examples, the gNB may indicate (e.g., explicitly indicate) to WTRU A and/or WTRU B the angular range of directions (e.g., 0°-45° with respect to a common reference point) and/or granularity to scan via indication(s) sent respectively to WTRU A and WTRU B (e.g., RRC signalling and/or messages, MAC CE, or DCI). The gNB may send an indication to the WTRU(s) about the presence of other WTRU(s) located in proximity, for example, leaving it to the WTRU(s) to perform measurements (e.g., over SL) and determine the angular range and/or granularity of directions for the WTRUs (e.g., each WTRU) to scan and compute channel estimates. A WTRU (e.g., each WTRU) may send an indication to the gNB of the angular range and/or granularity jointly determined.

Based on the gNB exploiting spatial correlations in CSI values between WTRUs, antenna elements, and/or channels/sub-channels, where the correlation may be determined by the WTRU or gNB, one or more of the following may apply. The WTRU may determine correlation (e.g., beyond a threshold configured by the WTRU or gNB) among antenna elements. The WTRU may determine correlation among antenna elements (e.g., λᵣₓ and/or λₜₓ) and perform measurements to determine if and/or how many antennas may be averaged and may send the indication to the gNB. Based on the indication sent by the WTRU, the gNB may reconfigure the reference signals. In examples, the WTRU may do discovery of other WTRU(s) in proximity via SL and jointly (e.g., with the other WTRU(s) discovered) determine whether there is correlation and/or a degree of correlation and whether this correlation may be exploited for CSI reporting. The WTRU may send the result of the joint determination to the gNB.

Feature(s) performed by a WTRU associated with supporting CSI compression by determining the pre-processing type for channel measurements are described. One or more of the following actions may be performed by a WTRU: sending a WTRU capability information message, e.g., indicating the WTRU has Al/ML CSI processing capabilit(ies), to the gNB; monitoring for an Al/ML based CSI compression configuration from the gNB; selecting a data processing model (e.g., an AI/ML NN encoder model) to be used for CSI compression, e.g., based on received CSI compression configuration and/or CSI reporting configuration; performing channel measurement(s) (e.g., channel response, CQI, PMI, RI, etc.), e.g., using configured reference signal(s); determining characteristic channel feature(s) (e.g., slow or fast varying channel, frequency selective or frequency flat channel, etc.) from the channel measurement(s); determining the pre-processing type, e.g., based on the determined channel characteristic(s) (e.g., channel condition(s)) and/or on the selected data processing model (e.g., AI/ML NN encoder model); pre-processing the channel measurements using the selected pre-processing type and, in some examples, parameters, such as those described herein; compressing the pre-processed channel measurements using the configured data processing model (e.g., AI/ML NN encoder model); reporting the determined pre-processing type and parameters to the gNB; or reporting the compressed CSI to the gNB

The above example may include one or more of the following. The WTRU capability information signaled by the WTRU may indicate whether the WTRU supports Al/ML NN encoder-based CSI compression and/or the maximum size of the AI/ML NN encoder model. The CSI compression configuration may include the size of the NN encoder model and/or the compression ratio. The WTRU may perform channel measurements for explicit CSI reporting, such as the channel response matrix for all Tx antenna ports and Rx antennas, at different granularities in frequency domain, for example, corresponding to the CSI-RS resource configuration. The WTRU may perform channel measurements (e.g., additional channel measurements), such as channel coherence time, channel coherence bandwidth, Doppler spread, SNR, etc. The WTRU may determine the pre-processing type to use, based on the measured channel characteristics. For example, the WTRU may determine to use frequency-domain pre-processing of the CSI, e.g., when the measured coherence bandwidth of the channel is larger than a configured threshold (e.g., configured by the gNB). The WTRU may determine to pre-process the channel matrix by averaging a number of adjacent channel estimates in frequency domain, for example, when the WTRU selects frequency-domain pre-processing. The WTRU may determine the number of adjacent channel estimates that are averaged, for example, as a fraction of the ratio between the coherence bandwidth of the channel and the configured frequency-domain CSI-RS granularity. In examples, the WTRU may perform frequency-domain pre-processing, for example, by down-sampling, where the down-sampling rate may be a fraction of the ratio between the coherence bandwidth of the channel and the configured frequency-domain CSI-RS granularity. The WTRU may select the pre-processing type (e.g., frequency-domain based or conversion to angular-delay domain), for example, by calculating the size of the pre-processed channel matrix and selecting the smallest. For example, selecting the pre-processing type may result in the smallest pro-processed data, e.g., at the input of the AI NN encoder. The WTRU may compress the pre-processed channel matrix using the configured/selected AI/ML NN encoder The WTRU may report the parameters of the selected pre-processing, for example, the selected pre-processing type and/or the pre-processing parameters (e.g., the number of adjacent channel samples that were averaged in frequency domain, matrix sizes, etc.). The WTRU may report the compressed CSI (e.g., to a gNB).

Technique(s) performed by a WTRU to support CSI compression by determining a pre-processing type and an AI NN encoder model are provided. The technique(s) may comprise one or more of the following actions: reporting WTRU capability information indicating the supported pre-processing types and AI NN encoder models (e.g., pre-configured AI NN encoder models); monitoring for the CSI report size (e.g., NTot) from the gNB (e.g., the WTRU may monitor for CSI compression quality configuration from the gNB); performing channel measurements (e.g., channel response, CQI, PMI, RI, etc.) using the configured reference signals; determining the characteristic channel features (e.g., slow/fast varying channel, frequency selective/frequency flat channel, etc.) from the channel measurements; determining the pre-processing type and the AI NN encoder model, e.g., based on the channel characteristics and the configured CSI report size (e.g., and/or quality); pre-processing the channel measurements using the determined pre-processing type (e.g., and parameters); compressing the pre-processed channel measurements using the determined AI NN encoder; reporting the determined pre-processing type and Al NN encoder model to the gNB; and/or reporting the compressed CSI to the gNB.

The above example may include one or more of the following. The WTRU may be pre-configured with a set of pre-processing types (e.g., pre-processing type a, referred to as frequency-domain; pre-processing type b, referred to as time domain; pre-processing type c, referred to as linear transformation to convert to angle-delay domain; . . . pre-processing type e, etc.). The WTRU may be pre-configured with a set of 3-D AI NN encoder models, for example, with the corresponding dimensions and/or parameters: Al model 1 (Nc1×NR1×NT1) and compression ratio 1 (CR1); Al model 2 (Nc2×NR2×NT2) and compression ratio 2 (CR2) and compression ratio (CR3), where different compression ratios CR2 and CR3 correspond to tapping outputs off different layers of the NN.

The above example may include one or more of the following. The WTRU may be configured with a set of values corresponding to the achieved compression quality individually for various pre-processing types and NN models. The compression quality metric may be based on the difference (e.g., mean squared error) between the actual CSI report quantity (e.g., channel response) and the estimated channel response after the compression and decompression using the indicated pre-processing/post-processing steps or compression/decompression using the NN. The values of the compression quality metric for each compression method and NN model may be specified (e.g., further specified) for different conditions (e.g., channel characteristics). A pre-processing type may be applicable to one or more of the supported AI NN encoder models. An AI NN encoder model may use multiple pre-processing types. The CSI report configuration may include the maximum number of CSI bits to be reported by the WTRU for the selected configuration (e.g., including selected CSI-RS resource configuration). The CSI report configuration may include the minimum compression quality expected by the gNB. The WTRU may perform channel measurements for explicit CSI reporting, such as the channel response matrix for all Tx antenna ports and Rx antennas, at different granularities in frequency domain, for example, corresponding to the CSI-RS resource configuration. The WTRU may perform additional channel measurements, such as channel coherence time, channel coherence bandwidth, Doppler spread, SNR, etc. The WTRU may select a subset of the pre-processing types, based on the measured channel characteristics. For example, the WTRU may select the frequency-domain pre-processing, for example, if the measured channel coherence BW is large (e.g., above a threshold).

The above example may include one or more of the following. For the selected subset of pre-processing types, the WTRU may determine that one or more combinations of AI NN encoder model and pre-processing types may meet the CSI report size. The WTRU may select the preferred pre-processing type and AI NN model, for example, so the CSI compression quality metric exceeds a threshold (e.g., a configured threshold). If more than one combination of pre-processing techniques and NN models achieve the CSI compression quality metric and the maximum number of allocated bits for the CSI report, the WTRU may choose a particular combination of pre-processing method and AI NN model to optimize one or more of criteria such as the value of the achieved compression quality metric, processing time, memory requirements, etc. The WTRU may pre-process the channel measurement, using the selected pre-processing type. The WTRU may compress the pre-processed channel matrix using the configured/selected AI/ML NN encoder. The WTRU may report the parameters of the selected pre-processing type and AI NN encoder model, for example, the selected pre-processing type, the pre-processing parameters, and/or the selected AI NN model. The WTRU may use explicit reporting or may use implicit reporting. The WTRU may report the compressed CSI.

Although features and elements described above are described in particular combinations, each feature or element may be used alone without the other features and elements of the preferred embodiments, or in various combinations with or without other features and elements.

Although the implementations described herein may consider 3GPP specific protocols, it is understood that the implementations described herein are not restricted to this scenario and may be applicable to other wireless systems. For example, although the solutions described herein consider LTE, LTE-A, New Radio (NR) or 5G specific protocols, it is understood that the solutions described herein are not restricted to this scenario and are applicable to other wireless systems as well. For example, while the system has been described with reference to a 3GPP, 5G, and/or NR network layer, the envisioned embodiments extend beyond implementations using a particular network layer technology. Likewise, the potential implementations extend to all types of service layer architectures, systems, and embodiments. The techniques described herein may be applied independently and/or used in combination with other resource configuration techniques.

The processes described herein may be implemented in a computer program, software, and/or firmware incorporated in a computer-readable medium for execution by a computer and/or processor. Examples of computer-readable media include, but are not limited to, electronic signals (transmitted over wired and/or wireless connections) and/or computer-readable storage media. Examples of computer-readable storage media include, but are not limited to, a read only memory (ROM), a random access memory (RAM), a register, cache memory, semiconductor memory devices, magnetic media such as, but not limited to, internal hard disks and removable disks, magneto-optical media, and/or optical media such as compact disc (CD)-ROM disks, and/or digital versatile disks (DVDs). A processor in association with software may be used to implement a radio frequency transceiver for use in a WTRU, terminal, base station, RNC, and/or any host computer.

It is understood that the entities performing the processes described herein may be logical entities that may be implemented in the form of software (e.g., computer-executable instructions) stored in a memory of, and executing on a processor of, a mobile device, network node or computer system. That is, the processes may be implemented in the form of software (e.g., computer-executable instructions) stored in a memory of a mobile device and/or network node, such as the node or computer system, which computer executable instructions, when executed by a processor of the node, perform the processes discussed. It is also understood that any transmitting and receiving processes illustrated in figures may be performed by communication circuitry of the node under control of the processor of the node and the computer-executable instructions (e.g., software) that it executes.

The various techniques described herein may be implemented in connection with hardware or software or, where appropriate, with a combination of both. Thus, the implementations and apparatus of the subject matter described herein, or certain aspects or portions thereof, may take the form of program code (e.g., instructions) embodied in tangible media including any other machine-readable storage medium wherein, when the program code is loaded into and executed by a machine, such as a computer, the machine becomes an apparatus for practicing the subject matter described herein. In the case where program code is stored on media, it may be the case that the program code in question is stored on one or more media that collectively perform the actions in question, which is to say that the one or more media taken together contain code to perform the actions, but that-in the case where there is more than one single medium—there is no requirement that any particular part of the code be stored on any particular medium. In the case of program code execution on programmable devices, the computing device generally includes a processor, a storage medium readable by the processor (including volatile and non-volatile memory and/or storage elements), at least one input device, and at least one output device. One or more programs that may implement or utilize the processes described in connection with the subject matter described herein, e.g., through the use of an API, reusable controls, or the like. Such programs are preferably implemented in a high level procedural or object oriented programming language to communicate with a computer system. However, the program(s) can be implemented in assembly or machine language, if desired. In any case, the language may be a compiled or interpreted language, and combined with hardware implementations.

Although example embodiments may refer to utilizing aspects of the subject matter described herein in the context of one or more stand-alone computing systems, the subject matter described herein is not so limited, but rather may be implemented in connection with any computing environment, such as a network or distributed computing environment. Still further, aspects of the subject matter described herein may be implemented in or across a plurality of processing chips or devices, and storage may similarly be affected across a plurality of devices. Such devices might include personal computers, network servers, handheld devices, supercomputers, or computers integrated into other systems such as automobiles and airplanes.

In describing preferred embodiments of the subject matter of the present disclosure, as illustrated in the Figures, specific terminology is employed for the sake of clarity. The claimed subject matter, however, is not intended to be limited to the specific terminology so selected, and it is to be understood that each specific element includes all technical equivalents that operate in a similar manner to accomplish a similar purpose.

1-18. (canceled)

19. A wireless transmit receive unit (WTRU) comprising:
a processor configured to:
receive configuration information that indicates a reference signal and a data processing model for channel state information (CSI) compression;
determine CSI associated with a channel using the reference signal;
determine a channel condition associated with pre-processing;
select a pre-processing type from a plurality of pre-processing types based on the data processing model and the channel condition associated with pre-processing;
pre-process the CSI associated with the channel based on the selected pre-processing type;
generate compressed CSI by compressing the pre-processed CSI using the data processing model for CSI compression;
send an indication of the selected pre-processing type to a network; and
send the compressed CSI to the network.

20. The WTRU of claim 19, wherein the processor being configured to select the pre-processing type comprises the processor being configured to select the pre-processing type based on a determination that the data processing model supports the pre-processing type.

21. The WTRU of claim 19, wherein the channel condition associated with pre-processing is determined based on a value of a channel measurement parameter.

22. The WTRU of claim 21, wherein the channel measurement parameter comprises a coherence bandwidth.

23. The WTRU of claim 19, wherein the pre-processing type comprises at least one of: spatial domain pre-processing, frequency domain pre-processing, angle-delay domain pre-processing, time domain pre-processing, or linear transformation pre-processing.

24. The WTRU of claim 19, wherein the processor being configured to select the pre-processing type comprises the processor being configured to:
determine that pre-processing the CSI using a first pre-processing type generates pre-processed CSI of a first size;
determine that pre-processing the CSI using a second pre-processing type generates pre-processed CSI of a second size;
select the first pre-processing type if the first size is smaller than the second size; and
select the second pre-processing type if the second size is smaller than the first size.

25. The WTRU of claim 19, wherein the channel condition comprises a channel spatial domain correlation, and the processor is further configured to:
compare the channel spatial domain correlation to a spatial domain correlation threshold; and
determine, based on the comparison, a level of spatial domain correlation, wherein the processor being configured to select the pre-processing type comprises the processor being configured to select the pre-processing type based on the level of spatial domain correlation.

26. The WTRU of claim 19, wherein the processor is further configured to:
obtain a first channel correlation at a first time and a second channel correlation at a second time;
determine a coherence time based on a value of the first channel correlation and a value of the second channel correlation; and
compare the coherence time to a coherence time threshold, wherein the processor being configured to select the pre-processing type comprises the processor being configured to select the pre-processing type based on the comparison.

27. A method comprising:
receiving configuration information that indicates a reference signal and a data processing model for channel state information (CSI) compression;
determining CSI associated with a channel using the reference signal;
determining a channel condition associated with pre-processing;
selecting a pre-processing type from a plurality of pre-processing types based on the data processing model and the channel condition associated with pre-processing;
pre-processing the CSI associated with the channel based on the selected pre-processing type;
generating compressed CSI by compressing the pre-processed CSI using the data processing model for CSI compression;
sending an indication of the selected pre-processing type to a network; and
sending the compressed CSI to the network.

28. The method of claim 27, wherein selecting the pre-processing type is based on a determination that the data processing model supports the pre-processing type.

29. The method of claim 27, wherein the channel condition associated with pre-processing is determined based on a value of a channel measurement parameter.

30. The method of claim 29, wherein the channel measurement parameter comprises a coherence bandwidth.

31. The method of claim 27, wherein the pre-processing type comprises at least one of: spatial domain pre-processing, frequency domain pre-processing, angle-delay domain pre-processing, time domain pre-processing, or linear transformation pre-processing.

32. The method of claim 27, wherein selecting the pre-processing type comprises:
determining that pre-processing the CSI using a first pre-processing type generates pre-processed CSI of a first size;
determining that pre-processing the CSI using a second pre-processing type generates pre-processed CSI of a second size;
selecting the first pre-processing type if the first size is smaller than the second size; and
selecting the second pre-processing type if the second size is smaller than the first size.

33. The method of claim 27, wherein the channel condition comprises a channel spatial domain correlation, and the method further comprises:
comparing the channel spatial domain correlation to a spatial domain correlation threshold; and
determining, based on the comparison, a level of spatial domain correlation, wherein selecting the pre-processing type is further based on the level of spatial domain correlation.

34. The method of claim 27, wherein the method further comprises:
obtaining a first channel correlation at a first time and a second channel correlation at a second time;
determining a coherence time based on a value of the first channel correlation and a value of the second channel correlation; and
comparing the coherence time to a coherence time threshold, wherein selecting the pre-processing type is further based on the comparison.

35. A wireless transmit/receive unit (WTRU) comprising:
a processor configured to:
identify a data processing model for channel state information (CSI) compression;
select a pre-processing type from a plurality of pre-processing types based on the data processing model;
pre-process CSI based on the selected pre-processing type;
generate compressed CSI by compressing the pre-processed CSI using the data processing model;
send an indication of the selected pre-processing type to a network; and
send the compressed CSI to the network.
